(19) United States
(12) Patent Application Publication
(10) Pub. No.: US 2025/0143047 A1
(43) Pub. Date: May 1, 2025

(54) DISPLAY DEVICE AND METHOD FOR MANUFACTURING THE SAME

(71) Applicant: Samsung Display Co., LTD., Yongin-si (KR)

(72) Inventors: Ki Seong SEO, Yongin-si (KR); Jong Moo HUH, Yongin-si (KR); Min Woo KIM, Yongin-si (KR); Myung Koo HUR, Yongin-si (KR); Hui Won YANG, Yongin-si (KR); Jae Phil LEE, Yongin-si (KR)

(21) Appl. No.: 18/927,338

(22) Filed: Oct. 25, 2024

(30) Foreign Application Priority Data
Oct. 31, 2023 (KR) 10-2023-0148181

(51) Int. Cl. H01L 33/62; H01L 25/16; H01L 33/48

(52) U.S. Cl. CPC H10H 20/857; H01L 25/167; H10H 20/8506; H10H 20/0364

(57) ABSTRACT

Provided are a display device and a method for manufacturing the same. According to one or more embodiments of the present disclosure, the display device includes a substrate, a bank on the substrate and comprising an opening, a pixel electrode and a common electrode spaced from each other on the substrate in the opening, an organic layer on the pixel electrode and the common electrode in the opening, a light emitting element on the organic layer, and comprising a first electrode and a second electrode on a top surface thereof, a first connection electrode connected to the pixel electrode and the first electrode of the light emitting element, and a second connection electrode connected to the common electrode and the second electrode of the light emitting element. The organic layer is on a bottom surface and at least a portion of one side surface of the light emitting element.

### CROSS-REFERENCE TO RELATED APPLICATION

The present application claims priority to and the benefit of Korean Patent Application No. 10-2023-0148181, filed on Oct. 31, 2023, in the Korean Intellectual Property Office, the entire disclosure of which is incorporated by reference herein.

### BACKGROUND

### 1. Field

One or more embodiments of the present disclosure relate to a display device and a method for manufacturing the same.

### 2. Description of the Related Art

With the advance of information-oriented society, more and more demands are placed on display devices for displaying images in various ways. The display device may be a flat panel display device such as a liquid crystal display, a field emission display and a light emitting display. The light emitting display may include an organic light emitting display including an organic light emitting diode element as a light emitting element, and an ultra-small light emitting display including an ultra-small light emitting diode element (hereinafter, referred to as a micro light emitting diode element) as a light emitting element.

When the micro light emitting element is a vertical micro light emitting element in which a first semiconductor layer, an active layer, a second semiconductor layer, and an undoped semiconductor layer are sequentially stacked in a perpendicular direction, the resistance of the undoped semiconductor layer is high, so that the luminous efficiency of the micro light emitting element may decrease or the micro light emitting element may not emit light.

### SUMMARY

Aspects and features of embodiments of the present disclosure provide a display device capable of reducing or preventing a luminous efficiency of a micro light emitting element from decreasing or the micro light emitting element from not emitting light due to a resistance of an undoped semiconductor layer and a method for manufacturing the same.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provided a display device including a substrate, a bank on the substrate and comprising an opening, a pixel electrode and a common electrode spaced from each other on the substrate in the opening, an organic layer on the pixel electrode and the common electrode in the opening, a light emitting element on the organic layer, and comprising a first electrode and a second electrode on a top surface thereof, a first connection electrode connected to the pixel electrode and the first electrode of the light emitting element, and a second connection electrode connected to the common electrode and the second electrode of the light emitting element. The organic layer is on a bottom surface and at least a portion of one side surface of the light emitting element.

The first connection electrode may be on the organic layer between the bank and the one side surface of the light emitting element. The second connection electrode may be on the organic layer between the bank and an other side surface of the light emitting element. The other side surface of the light emitting element may be a side surface opposite to the one side surface of the light emitting element.

A thickness of the organic layer may be less than a thickness of the bank.

The light emitting element may include a first semiconductor layer connected to the first electrode, an active layer connected to the first semiconductor layer, a second semiconductor layer comprising a first portion connected to the active layer and a second portion connected to the second electrode, and an undoped semiconductor layer connected to the second semiconductor layer.

A thickness of the first portion of the second semiconductor layer may be greater than a thickness of the second portion of the second semiconductor layer.

The undoped semiconductor layer may be on the organic layer. The second semiconductor layer may be on the undoped semiconductor layer. The active layer may be on the first portion of the second semiconductor layer. The first semiconductor layer may be on the active layer. The first electrode may be on the first semiconductor layer. The second electrode may be on the second portion of the second semiconductor layer.

A thickness of the second electrode may be greater than a thickness of the first electrode.

The organic layer may be on side and bottom surfaces of the undoped semiconductor layer and at least a portion of one side surface of the second semiconductor layer.

The first connection electrode may be on one side surface of the first semiconductor layer, one side surface of the active layer, and at least a portion of one side surface of the second semiconductor layer.

The second connection electrode may be on at least a portion of one side surface of the second electrode.

The second connection electrode may be on at least a portion of a top surface and the entire one side surface of the second electrode.

The organic layer may be on at least a portion of a top surface of the second portion of the second semiconductor layer.

An area of the organic layer may be larger than an area of the first connection electrode and an area of the second connection electrode.

An area of the pixel electrode may be larger than an area of the first connection electrode. An area of the common electrode may be larger than an area of the second connection electrode.

The pixel electrode and the common electrode may include an opaque metal material. The first connection electrode and the second connection electrode may include a transparent conductive oxide.

A thickness of the bank may be about 0.5 μm or more.

According to one or more embodiments of the present disclosure, there is provided a method for manufacturing a display device, including preparing a plurality of light emitting elements on a light emitting element substrate, forming a bank having a plurality of openings on a substrate, and forming a pixel electrode and a common electrode in each of the plurality of openings, forming an organic layer on the pixel electrode and the common electrode in each of the plurality of openings, adhering each of the plurality of light emitting elements of the light emitting element substrate to the organic layer in each of the plurality of openings, and forming a first connection electrode connecting the pixel electrode to a first electrode of the light emitting element on the organic layer, and a second connection electrode connecting the common electrode to a second electrode of the light emitting element.

The method may further include forming a light blocking layer on the bank, forming a first light conversion layer in a region corresponding to a first sub-pixel, forming a second light conversion layer in a region corresponding to a second sub-pixel, and forming a light transmitting layer in a region corresponding to a third sub-pixel, from among regions partitioned by the light blocking layer, and forming a first color filter on the first light conversion layer, forming a second color filter on the second light conversion layer, and forming a third color filter on the light transmitting layer.

The adhering of each of the plurality of light emitting elements of the light emitting element substrate to the organic layer in each of the plurality of openings may include curing the organic layer in each of the plurality of openings at a first temperature, inserting a portion of each of the plurality of light emitting elements into the organic layer in each of the plurality of openings, and curing the organic layer at a second temperature higher than the first temperature.

The adhering of each of the plurality of light emitting elements of the light emitting element substrate to the organic layer in each of the plurality of openings may include detaching each of the plurality of light emitting elements from the light emitting element substrate by using a stamp having an adhesive layer, inserting a portion of each of the plurality of light emitting elements into the organic layer in each of the plurality of openings, and detaching each of the plurality of light emitting elements from the stamp by applying heat to the adhesive layer of the stamp.

According to one or more embodiments of the present disclosure, there is provided a display device including a substrate, a pixel electrode and a common electrode spaced from each other on the substrate, an insulating layer on the substrate, and at least partially overlapping the pixel electrode and the common electrode, a light emitting element on the insulating layer, and comprising a first electrode and a second electrode, a first connection electrode electrically connected to the pixel electrode and the first electrode of the light emitting element, and a second connection electrode electrically connected to the common electrode and the second electrode of the light emitting element. At least one of the first electrode or the second electrode of the light emitting element includes an area exposed by the insulating layer.

According to the aforementioned and other embodiments of the present disclosure, both a first electrode and a second electrode of the light emitting element are on one surface of the light emitting element, so that the current of the light emitting element flows through the first electrode, a first semiconductor layer, an active layer, a first portion of a second semiconductor layer, a second portion of the second semiconductor layer, and the second electrode. Accordingly, since the current of the light emitting element does not flow through the undoped semiconductor layer, it is possible to reduce or prevent the luminous efficiency of the micro light emitting element from decreasing or the micro light emitting element from not emitting light due to the resistance of the undoped semiconductor layer.

### BRIEF DESCRIPTION OF THE DRAWINGS

The above and other embodiments and features of the present disclosure will become more apparent by describing embodiments thereof with reference to the attached drawings, in which:

FIG. 1 is a perspective view showing a display device according to one or more embodiments;

FIG. 2 is a layout diagram illustrating a display device according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is an equivalent circuit diagram illustrating a sub-pixel according to one or more embodiments;

FIG. 6 is a layout diagram showing a second power line and a plurality of pixels in a display area according to one or more embodiments;

FIG. 7 is a layout diagram showing in detail an example of an area A of FIG. 6;

FIG. 8 is a cross-sectional view showing an example of a cross section of the display panel corresponding to the lines I1-I1′, I2-I2′, and I3-I3′ of FIG. 6;

FIGS. 9A and 9B are cross-sectional views showing an example of a cross section of a light emitting element corresponding to line I2-I2′ of FIG. 6;

FIG. 10 is a layout view illustrating another example of the area A of FIG. 6 in detail;

FIG. 11 is a cross-sectional view showing an example of a cross section of a light emitting element corresponding to the line I3-I3′ of FIG. 6;

FIG. 12 is a flowchart illustrating a method for manufacturing a display device according to one or more embodiments;

FIGS. 13-19 are cross-sectional views illustrating a method for manufacturing a display device according to one or more embodiments;

FIG. 20 is a flowchart showing step S110 of FIG. 12 in detail;

FIGS. 21-27 are cross-sectional views for explaining step S110;

FIG. 28 is a diagram illustrating a virtual reality device including a display device according to one or more embodiments;

FIG. 29 is a diagram illustrating a smart watch including a display device according to one or more embodiments;

FIG. 30 is a diagram illustrating a dashboard of an automobile and a center fascia including display devices according to one or more embodiments; and

FIG. 31 is a diagram illustrating a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, about 2.4 to about 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip and/or on separate IC chips. Further, the various components of these devices may be implemented on a flexible printed circuit film, a tape carrier package (TCP), a printed circuit board (PCB), and/or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, and/or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

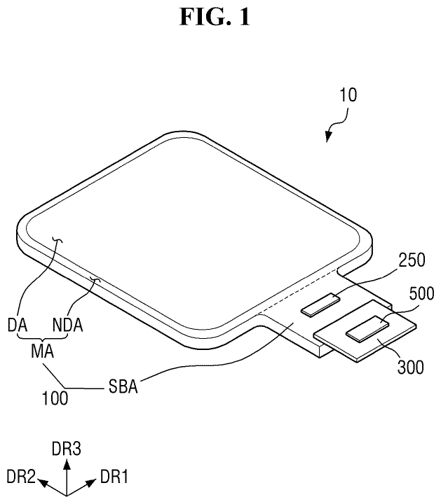

Referring to FIG. 1, a display device 10 is a device for displaying a moving image and/or a still image. The display device 10 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device, and/or an ultra-mobile PC (UMPC).

The display device 10 may be a light emitting display device such as an organic light emitting display using an organic light emitting diode (OLED), a quantum dot light emitting display including a quantum dot light emitting layer, an inorganic light emitting display including an inorganic semiconductor, and a micro light emitting display using a micro or nano light emitting diode (LED). In the following description, it is assumed that the display device 10 is a micro light emitting display device, but the present disclosure is not limited thereto. For simplicity of description, an ultra-small light emitting diode is referred to hereafter as a light emitting element.

The display device 10 includes a display panel 100, a display driving circuit 250, a circuit board 300, and a power supply circuit 500.

The display panel 100 may, in a plan view, may be formed in a rectangular shape having short sides in a first direction DR1 and long sides in a second direction DR2 crossing the first direction DR1. The corner where the short side in the first direction DR1 and the long side in the second direction DR2 meet may be rounded to have a suitable curvature (e.g., a predetermined curvature) or may be right-angled. The planar shape of the display panel 100 is not limited to the rectangular shape, and may be formed in another polygonal shape, a circular shape, or an elliptical shape. The display panel 100 may be formed to be flat, but is not limited thereto. For example, the display panel 100 may include a curved portion formed at left and right ends and having a constant curvature or a varying curvature. In addition, the display panel 100 may be formed flexibly so that it can be curved, bent, folded, and/or rolled.

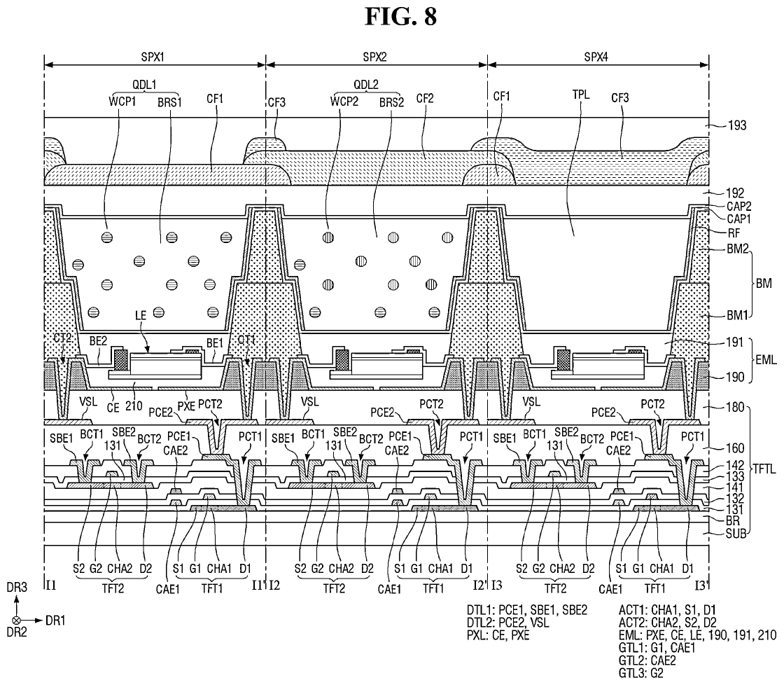

A substrate SUB (e.g., see FIG. 8) of the display panel 100 may include a main region MA and a sub-region SBA.

The main region MA may include a display area DA displaying an image and a non-display area NDA that is a peripheral area of the display area DA and is around (e.g., surrounds) the display area along an edge or a periphery of the display area DA. The display area DA may include a plurality of pixels displaying an image. For example, the pixel may include a first sub-pixel that emits first light, a second sub-pixel that emits second light, and a third sub-pixel that emits third light.

The sub-region SBA may protrude from one side of the main region MA in the second direction DR2. Although it is exemplarily shown in FIG. 1 that the sub-region SBA is unfolded, the sub-region SBA may be bent and, in this case, arranged on the bottom surface of the display panel 100. In the case where the sub-region SBA is bent, it may overlap the main region MA in a third direction DR3 that is a thickness direction of the display panel 100. The display driving circuit 250 may be arranged in the sub-region SBA.

The display driving circuit 250 may generate signals and voltages for driving the display panel 100. The display driving circuit 250 may be formed as an integrated circuit (IC) and attached onto the display panel 100 by a chip on glass (COG) method, a chip on plastic (COP) method, and/or an ultrasonic bonding method, but the present disclosure is not limited thereto. For example, the display driving circuit 250 may be attached onto the circuit board 300 by a chip on film (COF) method.

The circuit board 300 may be attached to one end of the sub-region SBA of the display panel 100. Thus, the circuit board 300 may be electrically connected to the display panel 100 and the display driving circuit 250. The display panel 100 and the display driving circuit 250 may receive digital video data, timing signals, and/or driving voltages through the circuit board 300. The circuit board 300 may be a flexible printed circuit board (FPCB), a printed circuit board (PCB), or a flexible film such as a chip on film.

The power supply circuit 500 may generate a plurality of panel driving voltages according to a power voltage from the outside. The power supply circuit 500 may be formed as an integrated circuit (IC) and attached to the circuit board 300 by a COF method.

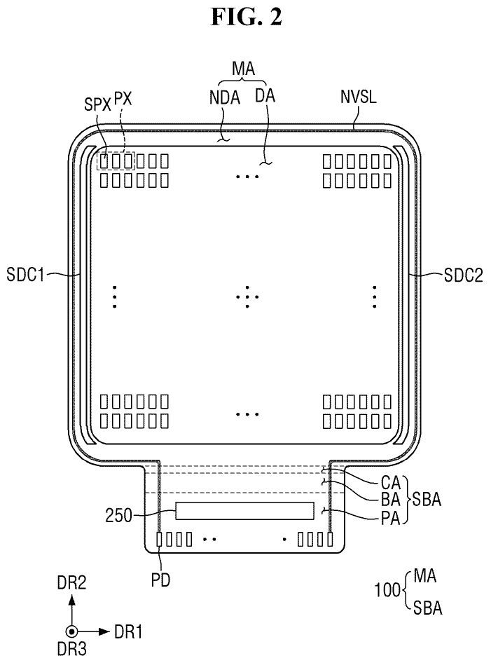

FIG. 2 is a layout view illustrating a display device according to one or more embodiments. It is shown in FIG. 2 as an example that the sub-region SBA is unfolded without being bent.

Referring to FIG. 2, the display panel 100 may include the main region MA and the sub-region SBA.

The main region MA may include the display area DA displaying an image and the non-display area NDA that is a peripheral area of the display area DA. The display area DA may occupy most of the main region MA. The display area DA may be disposed at the center of the main region MA.

The display area DA may include a plurality of pixels PX for displaying an image, and each of the plurality of pixels PX may include a plurality of sub-pixels SPX. The pixel PX may be defined as a minimum unit sub-pixel group capable of expressing a white grayscale.

The non-display area NDA may be disposed adjacent to the display area DA. The non-display area NDA may be an area outside the display area DA. The non-display area NDA may be disposed to be around (e.g., to surround) the display area DA. The non-display area NDA may be an edge area of the display panel 100.

A first scan driver SDC1 and a second scan driver SDC2 may be disposed in the non-display area NDA. The first scan driver SDC1 may be disposed at one side (for example, left side) of the display panel 100, and the second scan driver SDC2 may be disposed at the other side (for example, right side) of the display panel 100, but the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive scan control signals inputted from the display driving circuit 250, generate scan signals in response to the scan control signals, and output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be foldable to be disposed under the display panel 100. In this case, the sub-region SBA may overlap the main region MA in the third direction DR3.

The sub-region SBA may include a connection area CA, a pad area PA, and a bending area BA.

The connection area CA is an area protruding from one side of the main region MA in the second direction DR2. One side of the connection area CA may be in contact with the non-display area NDA of the main region MA, and the other side of the connection area CA may be in contact with the bending area BA.

The pad area PA is an area on which pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is an area being bent. When the bending area BA is bent, the pad area PA may be disposed under the connection area CA and the main region MA. The bending area BA may be disposed between the connection area CA and the pad area PA. One side of the bending area BA may be in contact with the connection area CA, and the other side of the bending area BA may be in contact with the pad area PA.

A non-display power line NVSL may be disposed in the non-display area NDA, the connection area CA, the bending area BA, and the pad area PA.

The non-display power line NVSL may be disposed on four sides of the display area DA in the non-display area NDA. The non-display power line NVSL may be disposed to be around (e.g., to surround) at least three sides of the display area DA. For example, the non-display power line NVSL may be around (e.g., may surround) the left side, upper side, and right side of the display area DA and may be disposed in at least a portion of the lower side. In addition, the non-display power line NVSL may be disposed outside the first scan driver SDC1 and outside the second scan driver SDC2. For example, the non-display power line NVSL may be disposed on the left side of the first scan driver SDC1 and on the right side of the second scan driver SDC2. The non-display power line NVSL may be disposed at the edges of the first scan driver SDC1 and the substrate SUB and at the edges of the second scan driver SDC2 and the substrate SUB. Alternatively, the non-display power line NVSL may overlap the first scan driver SDC1 and the second scan driver SDC2.

The non-display power line NVSL may be disposed on the left and right side edges in the connection area CA and bending area BA. The non-display power line NVSL may be connected to a pad PD adjacent to one side edge and the pad PD adjacent to the other side edge from among the pads PD in the pad area PA. The non-display power line NVSL may receive a second driving voltage VSS from the power supply circuit 500 disposed on the circuit board 300.

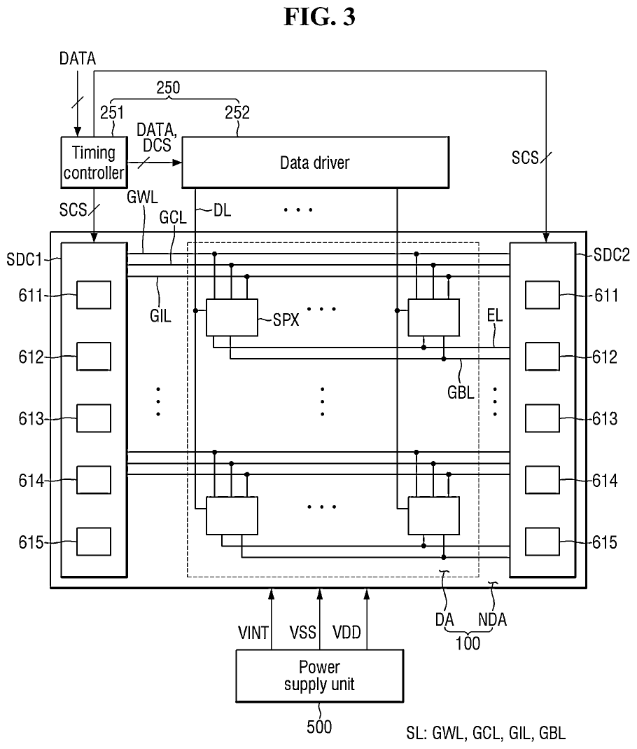

FIG. 3 is a block diagram illustrating a display device according to one or more embodiments.

Referring to FIG. 3, the display area DA includes a plurality of pixels PX, a plurality of scan lines SL (e.g., GWL, GCL, GIL, GBL), a plurality of emission control lines EL, and a plurality of data lines DL.

The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1, while being arranged along the second direction DR2. The plurality of data lines DL may extend in the second direction DR2, while being arranged along the first direction DR1. The plurality of scan lines SL include a plurality of write scan lines GWL, a plurality of control scan lines GCL, a plurality of initialization scan lines GIL, and a plurality of bias scan lines GBL.

Each of the plurality of sub-pixels SPX of a pixel PX may be connected to any one write scan line GWL from among the plurality of write scan lines GWL, any one control scan line GCL from among the plurality of control scan lines GCL, any one initialization scan line GIL from among the plurality of initialization scan line GIL, any one bias scan line GBL from among the plurality of bias scan lines GBL, any one emission control line EL from among the plurality of emission control lines EL, and any one data line DL from among the plurality of data lines DL. Each of the plurality of sub-pixels SPX may receive the data voltage of the data line DL according to the write scan signal of the write scan line GWL, and may emit light from a light emitting element thereof according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, a control scan signal output unit 612, an initialization scan signal output unit 613, a bias scan signal output unit 614, and an emission signal output unit 615. Each of the write scan signal output unit 611, the control scan signal output unit 612, the initialization scan signal output unit 613, the bias scan signal output unit 614, and the emission signal output unit 615 may receive a scan timing control signal SCS from a timing control circuit 251. The write scan signal output unit 611 may generate write scan signals according to the scan timing control signal SCS of the timing control circuit 251 and output them sequentially to the write scan lines GWL. The control scan signal output unit 612 may generate control scan signals in response to the scan timing control signal SCS and sequentially output them to the control scan lines GCL. The initialization scan signal output unit 613 may generate initialization scan signals in response to the scan timing control signal SCS and sequentially output them to the initialization scan lines GIL. The bias scan signal output unit 614 may generate bias scan signals according to the scan timing control signal SCS and output them sequentially to bias scan lines EBL. The emission signal output unit 615 may generate emission control signals according to the scan timing control signal SCS and sequentially output them to the emission control lines EL.

The display driving circuit 250 includes a timing control circuit 251 and a data driving circuit 252.

The data driving circuit 252 may receive the digital video data DATA and the data timing control signal DCS from the timing control circuit 251. The data driving circuit 252 converts the digital video data DATA into analog data voltages in response to the data timing control signal DCS, and outputs them to the data lines DL. In this case, the sub-pixels SPX may be selected by the write scan signal of the first scan driver SDC1 and the second scan driver SDC2, and data voltages may be supplied to the selected sub-pixels SPX.

The timing control circuit 251 may receive digital video data and timing signals from the outside. The timing control circuit 251 may generate the scan timing control signal SCS and a data timing control signal DCS for controlling the display panel 100 in response to the timing signals. The timing control circuit 251 may output the scan timing control signal SCS to the first scan driver SDC1 and the second scan driver SDC2. The timing control circuit 251 may output the digital video data DATA and the data timing control signal DCS to the data driving circuit 252.

The power supply circuit 500 may generate a plurality of panel driving voltages according to a power voltage from the outside. For example, the power supply circuit 500 may generate a first driving voltage VDD, the second driving voltage VSS, and a third driving voltage VINT and supply them to the display panel 100.

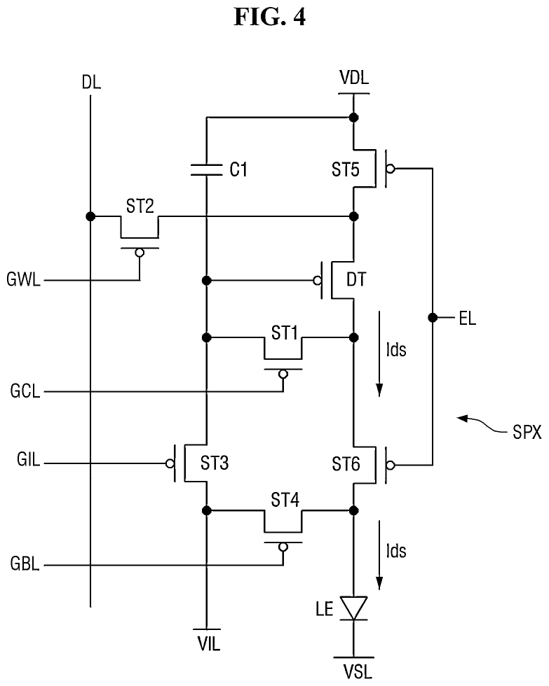

FIG. 4 is an equivalent circuit diagram illustrating a sub-pixel according to one or more embodiments.

Referring to FIG. 4, the sub-pixel SPX according to one or more embodiments may be connected to the scan lines GWL, GIL, GCL, and GBL, the emission line EL, and the data line DL. For example, the sub-pixel SPX may be connected to the write scan line GWL, the initialization scan line GIL, the control scan line GCL, the bias scan line GBL, the emission line EL, and the data line DL.

The sub-pixel SPX according to one or more embodiments includes a driving transistor DT, switch elements, a capacitor C1, and a light emitting element LE. The switch elements include the first to sixth transistors ST1, ST2, ST3, ST4, ST5, and ST6.

The driving transistor DT includes a gate electrode, a first electrode, and a second electrode. The driving transistor DT controls a drain-source current Ids (hereinafter, referred to as “driving current”) flowing between the first electrode and the second electrode according to a data voltage applied to the gate electrode of the driving transistor DT.

The light emitting element LE may be a micro light emitting diode element.

The light emitting element LE is configured to emit light according to the driving current Ids. The emission amount of the light emitting element LE may be proportional to the driving current Ids. The anode electrode of the light emitting element LE may be connected to the first electrode of the fourth transistor ST4 and the second electrode of the sixth transistor ST6, and the cathode electrode thereof may be connected to a second power line VSL to which a second power voltage is applied.

The capacitor C1 is formed between the gate electrode of the driving transistor DT and a first power line VDL to which a first power voltage is applied. The first power voltage may be the voltage having a level higher than that of the second power voltage. One electrode of the capacitor C1 may be connected to the gate electrode of the driving transistor DT, and the other electrode thereof may be connected to the first power line VDL.

As shown in FIG. 4, the first to sixth transistors ST1 to ST6, and the driving transistor DT may all be formed as p-type metal oxide semiconductor field effect transistors (MOSFETs). In this case, the active layer of each of the driving transistor DT and the first to sixth transistors ST1 to ST6 may be formed of polysilicon.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. The gate electrodes of the fifth and sixth transistors ST5 and ST6 may be connected to the emission line EL. Because the first to sixth transistors ST1 to ST6 are formed as p-type MOSFETs, they may be turned on when a scan signal and an emission signal of a gate low voltage are applied to the control scan line GCL, the initialization scan line GIL, and the write scan line GWL, the bias scan line GBL, and the emission line EL. One electrode of the third transistor ST3 and one electrode of the fourth transistor ST4 may be connected to the initialization voltage line VIL.

The first electrode of the first transistor ST1 may be connected to the second electrode of the driving transistor DT and the second electrode of the first transistor ST1 may be connected to the gate electrode of the driving transistor DT. As such, when the first transistor ST1 is turned on, the driving transistor may be diode-connected. The first electrode of the second transistor ST2 may be connected to a data line DL and the second electrode of the second transistor ST2 may be connected to the first electrode of the driving transistor DT. The first electrode of the third transistor ST3 may be connected to the gate electrode of the driving transistor DT and the second electrode of the third transistor ST3 may be connected to the initialization voltage line VIL. The first electrode of the fourth transistor ST4 may be connected to the second electrode of the sixth transistor ST6 and the second electrode of the fourth transistor ST4 may be connected to the initialization voltage line VIL. The first electrode of the fifth transistor ST5 may be connected to the first power supply line VDL and the second electrode of the fifth transistor ST5 may be connected to the first electrode of the driving transistor DT. The first electrode of the sixth transistor ST6 may be connected to the second electrode of the driving transistor DT and the second electrode of the sixth transistor ST6 may be connected to the anode electrode of the light emitting element LE.

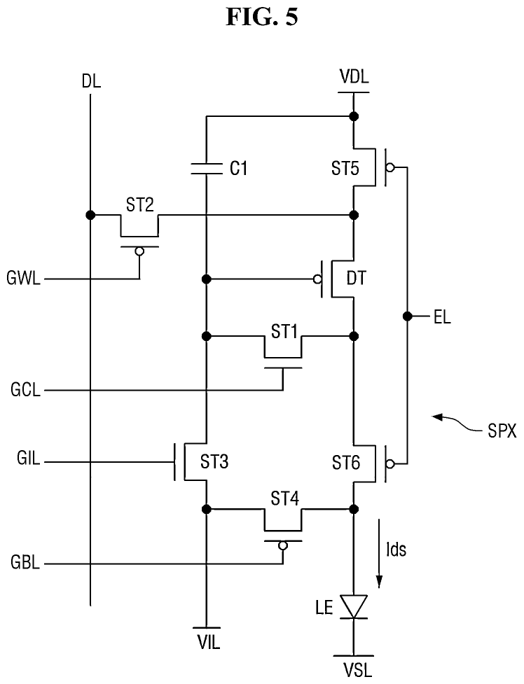

FIG. 5 is an equivalent circuit diagram illustrating a sub-pixel according to one or more embodiments.

Referring to FIG. 5, the driving transistor DT, the second transistor ST2, the fourth transistor ST4, the fifth transistor ST5, and the sixth transistor ST6 may be configured as p-type MOSFETs, and the first transistor ST1 and the third transistor ST3 may be configured as n-type MOSFETs. An active layer of each of the driving transistor DT, the second transistor ST2, the fourth transistor ST4, the fifth transistor ST5 and the sixth transistor ST6 configured as the P-type MOSFETs may be formed of polysilicon, whereas an active layer of each of the first transistor ST1 and the third transistor ST3 configured as the N-type MOSFETs may be formed of an oxide semiconductor. In this case, the transistors formed of polysilicon and the transistors formed of an oxide semiconductor may be disposed on different layers.

Because the first transistor ST1 and the third transistor ST3 are formed as n-type MOSFETs, the first transistor ST1 may be turned on when the control scan signal of a gate high voltage is applied to the control scan line GCL, and the third transistor ST3 may be turned on when the initialization scan signal is applied to the initialization scan line GIL. In contrast, because the second transistor ST2, the fourth transistor ST4, the fifth transistor ST5, and the sixth transistor ST6 are formed as p-type MOSFETs, they may be turned on when the emission signal and the scan signal of a gate low voltage are applied to each of the write scan line GWL, the bias scan line GBL, and the emission line EL.

Alternatively, in FIG. 4, the fourth transistor ST4 may be formed as an n-type MOSFET. In this case, the active layer of the fourth transistor ST4 may also be formed of an oxide semiconductor. When the fourth transistor ST4 is formed as an n-type MOSFET, it may be turned on when the bias scan signal of a gate high voltage is applied to the bias scan line GBL.

Alternatively, although not shown in FIGS. 4 and 5, the first to sixth transistors ST1 to ST6 and the driving transistor DT may all be formed as n-type MOSFETs. In this case, the active layer of each of the driving transistor DT and the first to sixth transistors ST1 to ST6 may be formed of an oxide semiconductor.

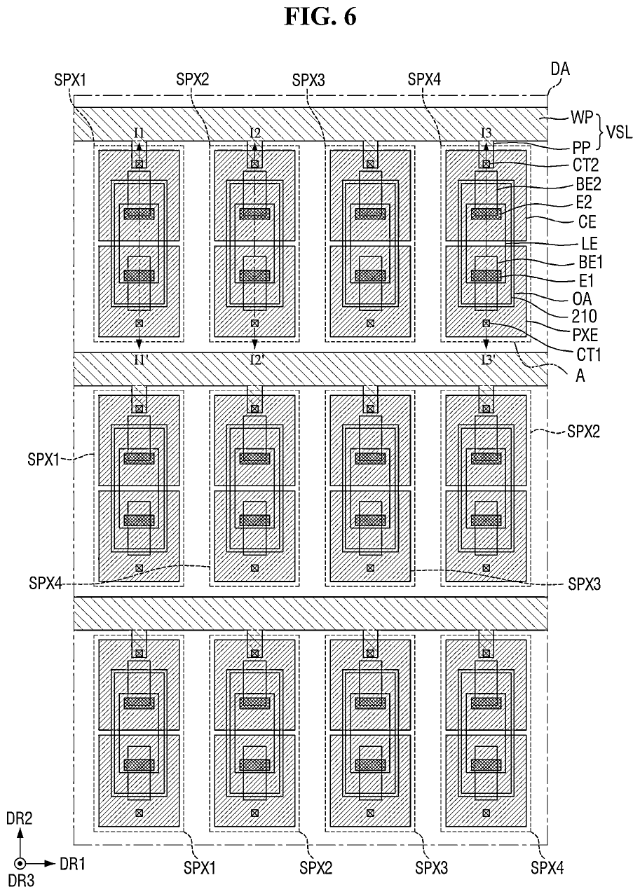

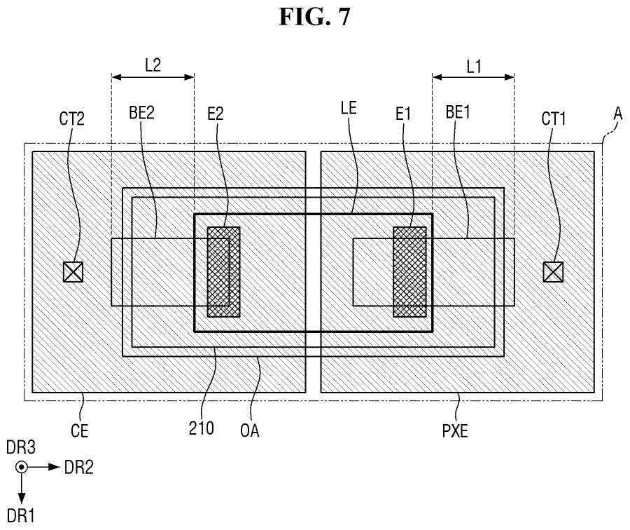

FIG. 6 is a layout diagram showing a second power line and a plurality of pixels in a display area according to one or more embodiments. FIG. 7 is a layout diagram showing in detail an example of an area A of FIG. 6.

Referring to FIGS. 6 and 7, each of the plurality of pixels PX in the display area DA may include a first sub-pixel SPX1, a second sub-pixel SPX2, a third sub-pixel SPX3, and a fourth sub-pixel SPX4.

The plurality of pixels PX may be arranged in a matrix. The first sub-pixel SPX1, the second sub-pixel SPX2, the third sub-pixel SPX3, and the fourth sub-pixel SPX4 in each of the plurality of pixels PX disposed in the N^{th} (N is a positive integer) row may be arranged in this order along the first direction DR1. The first sub-pixel SPX1, the fourth sub-pixel SPX4, the third sub-pixel SPX3, and the second sub-pixel SPX2 in each of the plurality of pixels PX disposed in the (N+1)^{th} (N is a positive integer) row may be arranged in this order along the first direction DR1.

Although it is exemplified that each of the first sub-pixel SPX1, the second sub-pixel SPX2, the third sub-pixel SPX3, and the fourth sub-pixel SPX4 has a rectangular planar shape, the present disclosure is not limited thereto. Each of the first sub-pixel SPX1, the second sub-pixel SPX2, the third sub-pixel SPX3, and the fourth sub-pixel SPX4 may have a quadrilateral shape other than a rectangular shape, a polygonal shape other than a quadrilateral shape, a circular shape, an elliptical shape, and/or an irregular shape. The planar shape of each of the first sub-pixel SPX1, the second sub-pixel SPX2, the third sub-pixel SPX3, and the fourth sub-pixel SPX4 may be defined in the shape of an area defined by a pixel electrode PXE and a common electrode CE. The first sub-pixel SPX1 and the third sub-pixel SPX3 may emit first light, the second sub-pixel SPX2 may emit second light, and the fourth sub-pixel SPX4 may emit third light. Here, the first light may be light of a green wavelength band, the second light may be light of a red wavelength band, and the third light may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm. When the first sub-pixel SPX1 and the third sub-pixel SPX3 emit light of a first color, light having low luminous efficiency may be compensated.

In the above, it is exemplified that the first sub-pixel SPX1 and the third sub-pixel SPX3 emit the same light, but the present disclosure is not limited thereto. For example, the first sub-pixel SPX1 may emit the first light, the second sub-pixel SPX2 may emit the second light, the third sub-pixel SPX3 may emit the third light, and the fourth sub-pixel SPX4 may emit fourth light. In this case, the fourth light may be light in a monochromatic wavelength band different from the first to third light, or may be white light that is mixed light of the first to third light.

However, the disposition and number of sub-pixels of each of the plurality of pixels PX and the emission wavelength band of the sub-pixels according to the present disclosure are not limited to those described above. For example, each of the plurality of pixels PX may include three sub-pixels arranged in a stripe shape. In this case, each of the plurality of pixels PX may include a first sub-pixel that emits the second light, a second sub-pixel that emits the first light, and a third sub-pixel that emits the third light. In each of the plurality of pixels PX, the first sub-pixel, the second sub-pixel, and the third sub-pixel may be sequentially disposed along the first direction DR1.

Each of the first to fourth sub-pixels SPX1 to SPX4 includes an opening OA, the pixel electrode PXE, the common electrode CE, the light emitting element LE, an organic layer 210, a first connection electrode BE1, a second connection electrode BE2, a first connection hole CT1, and a second connection hole CT2.

The opening OA may be a region partitioned by a bank 190 (see FIG. 8) and may be defined as an area in which the light emitting element LE is disposed in each of the first to fourth sub-pixels SPX1 to SPX4.

The pixel electrode PXE and the common electrode CE may be disposed to be spaced from each other. A portion of the pixel electrode PXE may be disposed in the first portion of the opening OA, and the remaining portion may be disposed in an area other than the opening OA. A portion of the common electrode CE may be disposed in the second portion of the opening OA, and the remaining portion may be disposed in an area other than the opening OA. The pixel electrode PXE and the common electrode CE may have substantially the same area, but the present disclosure is not limited thereto.

The organic layer 210 may be disposed to overlap the pixel electrode PXE and the common electrode CE in the opening OA. The organic layer 210 may serve to temporarily fix or adhere the light emitting element LE during the process of transferring the light emitting element LE to the display panel 100. That is, the organic layer 210 may be a layer for temporarily adhering the light emitting element LE to the pixel electrode PXE and the common electrode CE in the opening OA.

The area of the organic layer 210 may be larger than the areas of the first connection electrode BE1 and the second connection electrode BE2. The area of the pixel electrode PXE may be larger than the area of the first connection electrode BE1. The area of the common electrode CE may be larger than the area of the second connection electrode BE2.

The light emitting element LE may have a rectangular planar shape. The light emitting element LE includes a first electrode E1 disposed on one side and a second electrode E2 disposed on the other side. The first electrode E1 and the second electrode E2 may be spaced from each other in the second direction DR2.

The light emitting element LE may completely overlap the organic layer 210. A first portion of the light emitting element LE may overlap the pixel electrode PXE, and a second portion of the light emitting element LE may overlap the common electrode CE.

The first connection electrode BE1 serves to connect the first electrode E1 of the light emitting element LE to the pixel electrode PXE. To this end, the first connection electrode BE1 may be connected to the first electrode of the light emitting element LE and the pixel electrode PXE. The first connection electrode BE1 may overlap at least a portion of the first electrode E1. The first connection electrode BE1 may overlap at least a portion of the organic layer 210 and at least a portion of the pixel electrode PXE.

The second connection electrode BE2 serves to connect the second electrode E2 of the light emitting element LE to the common electrode CE. To this end, the second connection electrode BE2 may be connected to the second electrode E2 of the light emitting element LE and the common electrode CE. The second connection electrode BE2 may overlap at least a portion of the second electrode E2. The second connection electrode BE2 may overlap at least a portion of the organic layer 210 and at least a portion of the common electrode CE.

The first connection hole CT1 may be an area in which the pixel electrode PXE is electrically connected to a fourth source connection electrode PCE2 (see FIG. 8) that is electrically connected to a first source region S1 or a first drain region D1 of a first thin film transistor TFT1 (see FIG. 8). The first connection hole CT1 may overlap the pixel electrode PXE.

The second connection hole CT2 may be an area in which the common electrode CE is connected to the second power line VSL. The second connection hole CT2 may overlap the common electrode CE and the second power line VSL.

Each of the second power lines VSL may be electrically connected to the non-display power line NVSL disposed in the non-display area NDA as illustrated in FIG. 2. Each of the second power lines VSL may include a line portion WP extending in the first direction DR1 and a protrusion PP that protrudes from the line portion WP in the second direction DR2 and overlaps the second connection hole CT2.

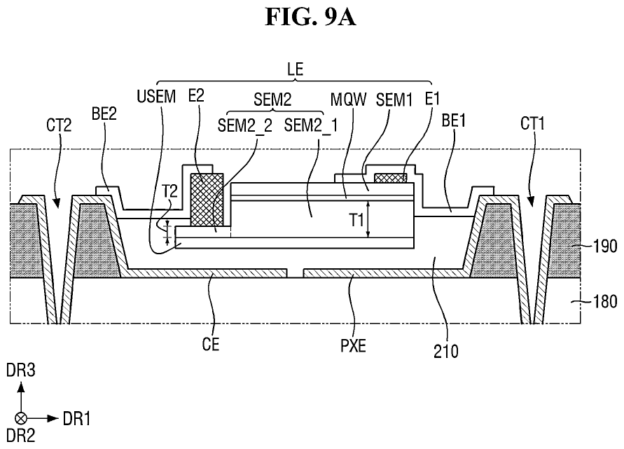

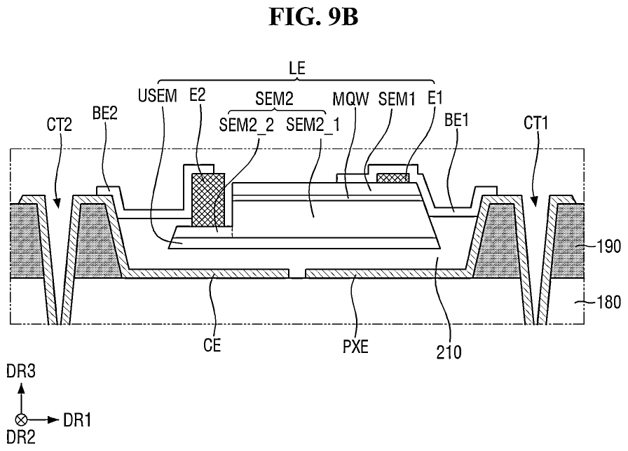

FIG. 8 is a cross-sectional view showing an example of a cross section of the display panel corresponding to the lines I1-I1′, I2-I2′, and I3-I3′ of FIG. 6. FIG. 9A is a cross-sectional view showing an example of a cross section of a light emitting element corresponding to the line I2-I2′ of FIG. 6.

Referring to FIGS. 8 and 9A, the substrate SUB may be made of an insulating material such as glass and/or polymer resin. When the substrate SUB is made of polymer resin, it may be a flexible substrate that can be stretched. The polymer resin may include acryl resin, epoxy resin, phenolic resin, polyamide resin, and/or polyimide resin.

The barrier layer BR may be disposed on the substrate SUB. The barrier layer BR is a layer for protecting transistors of the thin film transistor layer TFTL and a light emitting layer (e.g., the active layer MQW) of the light emitting element layer EML from moisture permeating through the substrate SUB which is susceptible to moisture permeation. The barrier layer BR may be formed as a plurality of inorganic layers that are alternately stacked. For example, the barrier layer BR may be formed of multiple layers in which one or more inorganic layers of a silicon nitride layer, a silicon oxynitride layer, a silicon oxide layer, a titanium oxide layer, and/or an aluminum oxide layer are alternately stacked.

The first thin film transistor TFT1 may be disposed on the barrier layer BR. The first thin film transistor TFT1 may be one of the fourth transistor ST4 and the sixth transistor ST6 shown in FIG. 5. The first thin film transistor TFT1 may include a first active layer ACT1 and a first gate electrode G1.

The first active layer ACT1 of the first thin film transistor TFT1 may be disposed on the barrier layer BR. The first active layer ACT1 of the first thin film transistor TFT1 may include polycrystalline silicon, monocrystalline silicon, low-temperature polycrystalline silicon, and/or amorphous silicon.

The first active layer ACT1 may include a first channel region CHA1, a first source region S1, and a first drain region D1. The first channel region CHA1 may be a region overlapping the first gate electrode G1 in the third direction DR3 that is the thickness direction of the substrate SUB. The first source region S1 may be disposed on one side of the first channel region CHA1, and the first drain region D1 may be disposed on the other side of the first channel region CHA1. The first source region S1 and the first drain region D1 may be regions that do not overlap the first gate electrode G1 in the third direction DR3. The first source region S1 and the first drain region D1 may be regions having conductivity by doping a silicon semiconductor with ions.

A first gate insulating layer 131 may be disposed on the first channel region CHA1, the first source region S1, and the first drain region D1 of the first thin film transistor TFT1 and the barrier layer BR. The first gate insulating layer 131 may be formed of an inorganic layer, for example, a silicon nitride layer, a silicon oxynitride layer, a silicon oxide layer, a titanium oxide layer, and/or an aluminum oxide layer.

A first gate metal layer GTL1 may be disposed on the first gate insulating layer 131. The first gate metal layer GTL1 may include the first gate electrode G1 and the first capacitor electrode CAE1 of the first thin film transistor TFT1. The first gate electrode G1 may overlap the first active layer ACT1 in the third direction DR3. FIG. 7 illustrates that the first gate electrode G1 and the first capacitor electrode CAE1 are spaced from each other, but the first gate electrode G1 and the first capacitor electrode CAE1 may be connected to each other. The first gate metal layer GTL1 may be formed as a single layer or multiple layers made of one of molybdenum (Mo), aluminum (Al), chromium (Cr), gold (Au), titanium (Ti), nickel (Ni), neodymium (Nd), and/or copper (Cu), and/or an alloy thereof.

A second gate insulating layer 132 may be disposed on the first gate electrode G1 and the first capacitor electrode CAE1 of the first thin film transistor TFT1 and the first gate insulating layer 131. The second gate insulating layer 132 may be formed of an inorganic layer, for example, a silicon nitride layer, a silicon oxynitride layer, a silicon oxide layer, a titanium oxide layer, and/or an aluminum oxide layer.

A second gate metal layer GTL2 may be disposed on the second gate insulating layer 132. The second gate metal layer GTL2 may include a second capacitor electrode CAE2. The second capacitor electrode CAE2 may overlap the first capacitor electrode CAE1 in the third direction DR3. Because the second interlayer insulating layer 132 has a desired dielectric constant (e.g., a predetermined dielectric constant), the capacitor C1 (FIG. 5) may be formed by the first capacitor electrode CAE1, the second capacitor electrode CAE2, and the second interlayer insulating layer 132 disposed therebetween. The second gate metal layer GTL2 may be formed as a single layer or multiple layers made of one of molybdenum (Mo), aluminum (Al), chromium (Cr), gold (Au), titanium (Ti), nickel (Ni), neodymium (Nd) and/or copper (Cu), and/or an alloy thereof.

A first interlayer insulating layer 141 may be disposed on the second capacitor electrode CAE2 and the second gate insulating layer 132. The first interlayer insulating layer 141 may be formed of an inorganic layer, for example, a silicon nitride layer, a silicon oxynitride layer, a silicon oxide layer, a titanium oxide layer, and/or an aluminum oxide layer.

A second thin film transistor TFT2 may be disposed on the first interlayer insulating layer 141. The second thin film transistor TFT2 may be one of the first transistor ST1 and the third transistor ST3 shown in FIG. 5. The second thin film transistor TFT2 may include the second active layer ACT2 and a second gate electrode G2.

The second active layer ACT2 of the second thin film transistor TFT2 may be disposed on the first interlayer insulating layer 141. The second active layer ACT2 may include an oxide semiconductor. For example, the second active layer ACT2 may be include IGZO (indium (In), gallium (Ga), zinc (Zn) and oxygen (O)), IGZTO (indium (In), gallium (Ga), zinc (Zn), tin (Sn), and/or oxygen (O)), or IGTO (indium (In), gallium (Ga), tin (Sn), and/or oxygen (O)).

The second active layer ACT2 may include a second channel region CHA2, a second source region S2, and a second drain region D2. The second channel region CHA2 may a region overlapping the second gate electrode G2 in the third direction DR3. The second source region S2 may be disposed on one side of the second channel region CHA2, and the second drain region D2 may be disposed on the other side of the second channel region CHA2. The second source region S2 and the second drain region D2 may be regions that do not overlap the second gate electrode G2 in the third direction DR3. The second source region S2 and the second drain region D2 may be regions having conductivity by doping an oxide semiconductor with ions.

A third gate insulating layer 133 may be disposed on the second active layer ACT2 of the second thin film transistor TFT2 and the first interlayer insulating layer 141. The third gate insulating layer 133 may be formed of an inorganic layer, for example, a silicon nitride layer, a silicon oxynitride layer, a silicon oxide layer, a titanium oxide layer, and/or an aluminum oxide layer.

A third gate metal layer GTL3 may be disposed on the third gate insulating layer 133. The third gate metal layer GTL3 may include the second gate electrode G2 of the second thin film transistor TFT2. The second gate electrode G2 may overlap the second active layer ACT2 in the third direction DR3. The third gate metal layer GTL3 may be formed as a single layer or multiple layers made of one of molybdenum (Mo), aluminum (Al), chromium (Cr), gold (Au), titanium (Ti), nickel (Ni), neodymium (Nd), and/or copper (Cu), and/or an alloy thereof.

A second interlayer insulating layer 142 may be disposed on the second gate electrode G2 of the second thin film transistor TFT2 and third gate insulating layer 133. The second interlayer insulating layer 142 may be formed of an inorganic layer, for example, a silicon nitride layer, a silicon oxynitride layer, a silicon oxide layer, a titanium oxide layer, and/or an aluminum oxide layer.

The first data metal layer DTL1 may be disposed on the second interlayer insulating layer 142. The first data metal layer DTL1 may include a first source connection electrode PCE1, a second source connection electrode SBE1, and a third source connection electrode SBE2. The first source connection electrode PCE1 may be connected to the first drain region D1 of the first active layer ACT1 through a first source connection hole PCT1 penetrating the first gate insulating layer 131, the second gate insulating layer 132, the first interlayer insulating layer 141, the third gate insulating layer 133, and the second interlayer insulating layer 142. The second source connection electrode SBE1 may be connected to the second source region S2 of the second active layer ACT2 through a second source connection hole BCT1 penetrating the second interlayer insulating layer 142 and the third gate insulating layer 133. The third source connection electrode SBE2 may be connected to the second drain region D2 of the second active layer ACT2 through a third source connection hole BCT2 penetrating the second interlayer insulating layer 142 and the third gate insulating layer 133. The first data metal layer DTL1 may be formed as a single layer or multiple layers made of one of molybdenum (Mo), aluminum (Al), chromium (Cr), gold (Au), titanium (Ti), nickel (Ni), neodymium (Nd) and/or copper (Cu), and/or an alloy thereof. For example, the first data metal layer DTL1 may include a first layer made of titanium (Ti), a second layer made of aluminum (Al), and a third layer made of titanium (Ti).

On the second interlayer insulating layer 142 and the first source connection electrode PCE1, the second source connection electrode SBE1, and the third source connection electrode SBE2, a first organic layer 160 for flattening the stepped portion caused by the first thin film transistor TFT1 and the second thin film transistor TFT2 may be disposed. The first organic layer 160 may be formed of an organic layer such as acryl resin, epoxy resin, phenolic resin, polyamide resin, polyimide resin, and/or the like.

The second data metal layer DTL2 may be disposed on the first organic layer 160. The second data metal layer DTL2 may include the fourth source connection electrode PCE2 and the second power line VSL. The fourth source connection electrode PCE2 may be connected to the first source connection electrode PCE1 through a second pixel connection hole PCT2 penetrating the first organic layer 160. The second power line VSL may be supplied with the second driving voltage VSS. The second data metal layer DTL2 may be formed as a single layer or multiple layers made of one of molybdenum (Mo), aluminum (Al), chromium (Cr), gold (Au), titanium (Ti), nickel (Ni), neodymium (Nd), and/or copper (Cu), and/or an alloy thereof. For example, the second data metal layer DTL2 may include a first layer made of titanium (Ti), a second layer made of aluminum (Al), and a third layer made of titanium (Ti).

A second organic layer 180 may be disposed on the first organic layer 160, the fourth source connection electrode PCE2, and the second power line VSL. The second organic layer 180 may be formed of an organic layer such as acryl resin, epoxy resin, phenolic resin, polyamide resin, polyimide resin, and/or the like.

The light emitting element layer EML may be disposed on the second organic layer 180. The light emitting element layer EML may include the pixel electrodes PXE, the bank 190, the light emitting elements LE, the common electrode CE, the organic layer 210, the first connection electrode BE1, the second connection electrode BE2, and the third organic layer 191.

The bank 190 may be disposed on the second organic layer 180. The bank 190 may be formed of an organic layer such as acryl resin, epoxy resin, phenolic resin, polyamide resin, polyimide resin, and/or the like. The bank 190 may include a light blocking material to prevent light of the light emitting element LE of any one sub-pixel from traveling to the neighboring sub-pixel. For example, the bank 190 may include an organic block pigment or an inorganic black pigment such as carbon black or the like.

The opening OA may be a region partitioned by the bank 190. The opening OA may be an area in which the bank 190 is not disposed and the second organic layer 180 is exposed.

The pixel electrode layer PXL may include the pixel electrode PXE and the common electrode CE disposed in each of the sub-pixels SPX1, SPX2, SPX3, and SPX4. The pixel electrode PXE may be referred to as an anode electrode, and the common electrode CE may be referred to as a cathode electrode.

The pixel electrode PXE and the common electrode CE may be disposed on the second organic layer 180 and the bank 190. The pixel electrode PXE and the common electrode CE may be disposed on the second organic layer 180 in the opening OA. The pixel electrode PXE and the common electrode CE may be disposed on the side surface and top surface of the bank 190. The pixel electrode PXE and the common electrode CE may be disposed apart (e.g., spaced) from each other.

The pixel electrode PXE may be connected to the fourth source connection electrode PCE2 through the first connection hole CT1 penetrating the second organic layer 180 and the bank 190. The pixel electrode PXE may be connected to the first source region S1 or the first drain region D1 of the first thin film transistor TFT1 through the first source connection electrode PCE1 and the fourth source connection electrode PCE2. Accordingly, the voltage controlled by the first thin film transistor TFT1 may be applied to the pixel electrode PXE.

The common electrode CE may be connected to the second power line VSL through the second connection hole CT2 penetrating the second organic layer 180 and the bank 190. Accordingly, the second driving voltage VSS may be applied to the common electrode CE.

When the pixel electrode layer PXL is made of a metal material with high reflectivity, from among the light emitted from an active layer MQW of the light emitting element LE, the light traveling in a downward direction with respect to the light emitting element LE may be reflected from the pixel electrode PXE and the common electrode CE to travel in an upward direction with respect to the light emitting element LE. Accordingly, because light loss from the light emitting element LE may be reduced, the light efficiency of the light emitting element LE may be increased. For example, the pixel electrode layer PXL may be formed as a single layer or multiple layers made of one of molybdenum (Mo), aluminum (Al), silver (Ag), platinum (Pt), palladium (Pd), chromium (Cr), gold (Au), titanium (Ti), nickel (Ni), neodymium (Nd), and/or copper (Cu), and/or an alloy thereof. Specifically, the pixel electrode layer PXL may have a three-layer structure of titanium (Ti)/aluminum (Al)/titanium (Ti), a two-layer structure of titanium (Ti)/copper (Cu), and/or a three-layer structure of titanium (Ti)/copper (Cu)/aluminum (Al), but the present disclosure is not limited thereto.

The organic layer 210 corresponding to an insulating layer may be disposed on the pixel electrode PXE and the common electrode CE in each of the sub-pixels SPX1, SPX2, SPX3, and SPX4. The organic layer 210 serves to temporarily fix or adhere the light emitting element LE during the process of transferring the light emitting element LE to the display panel 100. That is, the organic layer 210 may be a layer for temporarily adhering the light emitting element LE on the pixel electrode PXE and the common electrode CE. The larger the thickness of the organic layer 210, the easier temporary adhesion, so the height of the opening OA in which the organic layer 210 is accommodated or the thickness of the bank 190 may be about 0.5 μm or more. The height of the opening OA may be greater than the thickness of the organic layer 210. The thickness of the organic layer 210 may be greater than the thickness of each of the pixel electrodes PXE.

The organic layer 210 may be in contact with the bottom surface of the light emitting element LE. In addition, the organic layer 210 may be in contact with at least a portion of each of the side surfaces of the light emitting element LE.

The organic layer 210 may be a photosensitive organic layer such as a photoresist. Alternatively, the organic layer 210 may be formed of acryl resin, epoxy resin, phenolic resin, polyamide resin, polyimide resin, and/or the like.

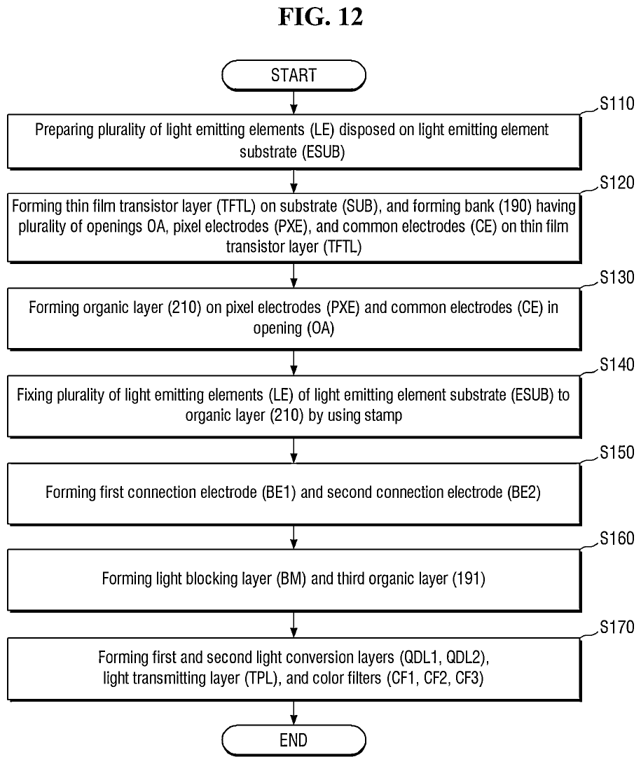

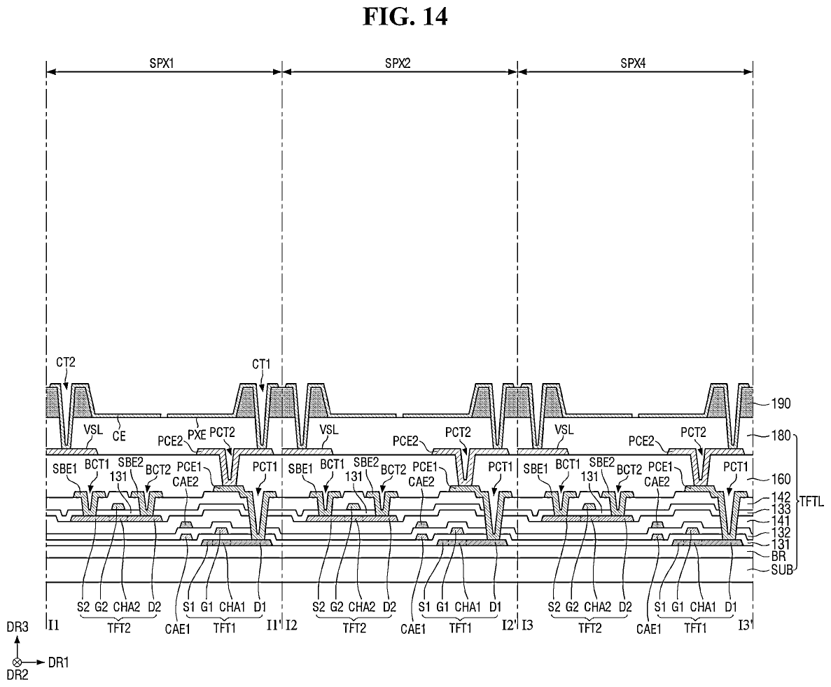

A detailed description of the organic layer 210 will be described later in the method for manufacturing the display device 10 with reference to FIGS. 12-19.

The light emitting element LE in each of the sub-pixels SPX1, SPX2, SPX3, and SPX4 may be disposed on the organic layer 210. As illustrated in FIGS. 8 and 9A, the light emitting element LE is exemplified as a lateral type micro LED in which both the first electrode E1 and the second electrode E2 protrude from the top surface of the light emitting element LE and the current flows in the lateral direction.

Each of the plurality of light emitting elements LE may be made of an inorganic material such as gallium nitride (GaN). Each of the plurality of light emitting elements LE may have a length of several to several hundreds of μm in each of the first direction DR1, the second direction DR2, and the third direction DR3. For example, each of the plurality of light emitting elements LE may have a length of about 100 μm or less in each of the first direction DR1, the second direction DR2, and the third direction DR3.

The length of the bottom surface of each of a plurality of light emitting elements LE may be longer than the length of the top surface. Although FIG. 9A illustrates that the angle formed by the side surface connecting the top surface and bottom surface of each of the plurality of light emitting elements LE with each of the top surface and the bottom surface is 90°, the present disclosure is not limited thereto. As illustrated in FIG. 9B, the angle formed by the side surface connecting the top surface and bottom surface of each of the plurality of light emitting elements LE with the top surface may be an obtuse angle, and the angle formed with the bottom surface may be an acute angle. That is, the side surface connecting the top surface and bottom surface of each of the plurality of light emitting elements LE may be an inclined surface.

The plurality of light emitting elements LE may be formed by growing on a semiconductor substrate such as a silicon substrate and/or sapphire substrate. The plurality of light emitting elements LE may be directly transferred from the semiconductor substrate onto the organic layer 210 of the display panel 100. Alternatively, the plurality of light emitting elements LE may be transferred onto the organic layer 210 of the display panel 100 through an electrostatic method using an electrostatic head or a stamping method using an elastic polymer material such as PDMS or silicon as a transfer substrate.

Each of the plurality of light emitting elements LE includes the first electrode E1, the second electrode E2, a first semiconductor layer SEM1, the active layer MQW, a second semiconductor layer SEM2, an undoped semiconductor layer USEM. In one or more embodiments, each of the plurality of light emitting elements LE also includes a passivation layer.

The undoped semiconductor layer USEM may be disposed on the organic layer 210. The undoped semiconductor layer USEM may be formed as a semiconductor layer that is not doped with an n-type dopant or a p-type dopant, that is, an undoped semiconductor layer. For example, the undoped semiconductor layer USEM may be one of InAlGaN, GaN, AlGaN, InGaN, AlN, and/or InN, which is not doped with a dopant. For example, the undoped semiconductor layer USEM may be GaN that is not doped with a dopant.

The second semiconductor layer SEM2 may be disposed on the undoped semiconductor layer USEM. The second semiconductor layer SEM2 may be one of InAlGaN, GaN, AlGaN, InGaN, AlN, and/or InN doped with an n-type dopant such as Si, Ge, and/or Sn. For example, the second semiconductor layer SEM2 may be n-GaN doped with n-type Si. The second semiconductor layer SEM2 may include a first portion SEM2_1 having a first thickness T1 and a second portion SEM2_2 having a second thickness T2 that is smaller than the first thickness T1.

The active layer MQW may be disposed on the first portion SEM2_1 of the second semiconductor layer SEM2. The active layer MQW may emit light by coupling of electron-hole pairs according to an electrical signal applied through the first semiconductor layer SEM1 and the second semiconductor layer SEM2.

The active layer MQW may include a material having a single or multiple quantum well structure. When the active layer MQW includes a material having a multiple quantum well structure, the active layer MQW may have the structure in which a plurality of well layers and barrier layers are alternately stacked. At this time, the well layer may be formed of InGaN, and the barrier layer may be formed of GaN and/or AlGaN, but the present disclosure is not limited thereto. Alternatively, the active layer MQW may have a structure in which semiconductor materials having large band gap energy and semiconductor materials having small band gap energy are alternately stacked, and may include other Group III to V semiconductor materials according to the wavelength band of the emitted light.

When the active layer MQW includes InGaN, the color of emitted light may vary depending on the content of indium (In). For example, as the content of indium (In) increases, the wavelength band of the light emitted by the active layer may shift to the red wavelength band, and as the content of indium (In) decreases, the wavelength band of the light emitted by the active layer may shift to the blue wavelength band. For example, the active layer MQW of the light emitting element LE that emits the third light (light in the blue wavelength band) may include about 10 wt % to 20 wt % of indium (In).

The first semiconductor layer SEM1 may be disposed on the active layer MQW. The first semiconductor layer SEM1 may be one of InAlGaN, GaN, AlGaN, InGaN, AlN, and/or InN doped with a p-type dopant such as Mg, Zn, Ca, Se, and/or Ba. For example, the first semiconductor layer SEM1 may be p-GaN doped with p-type Mg.

The first electrode E1 may be disposed on at least a portion of the first semiconductor layer SEM1. The first electrode E1 may include one of molybdenum (Mo), aluminum (Al), chromium (Cr), gold (Au), titanium (Ti), nickel (Ni), neodymium (Nd), and/or copper (Cu).

The second electrode E2 may be disposed on at least a portion of the second portion SEM2_2 of the second semiconductor layer SEM2. Not only are the active layer MQW and the first semiconductor layer SEM1 not disposed on the second portion SEM2_2 of the second semiconductor layer SEM2, but also the thickness T2 of the second portion SEM2_2 of the second semiconductor layer SEM2 is smaller than the thickness T1 of the first portion SEM2_1. Accordingly, in order to compensate for the thickness difference between the first portion SEM2_1 and the second portion SEM2_2 of the second semiconductor layer SEM2, the thickness of the active layer MQW, and the thickness of the first semiconductor layer SEM1, the thickness of the second electrode E2 may be greater than the thickness of the first electrode E1. For example, the thickness of the second electrode E2 may be more than the sum of the thickness difference between the first portion SEM2_1 and the second portion SEM2_2 of the second semiconductor layer SEM2, the thickness of the active layer MQW, and the thicknesses of the first semiconductor layer SEM1.

As illustrated in FIG. 9A, in the present disclosure, at least one of the first electrode E1 or the second electrode E2 may include an area exposed by the organic layer 210. That is, the entire area of the first electrode E1 may not be covered by the organic layer 210, a partial area of the second electrode E2 may be covered by the organic layer 210, and the remaining area of the second electrode E2 may be exposed without being covered by the organic layer 210.

The electron blocking layer may be disposed between the first semiconductor layer SEM1 and the active layer MQW. The electron blocking layer may be a layer for suppressing or preventing too many electrons from flowing into the active layer MQW. For example, the electron blocking layer may be AlGaN and/or p-AlGaN doped with p-type Mg. The electron blocking layer may be omitted.

The superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

In one or more embodiments, a passivation layer may be a layer to protect the side surfaces of the light emitting element LE. The passivation layer may be disposed on side surfaces of the first semiconductor layer SEM1, side surfaces of the active layer MQW, and side surfaces of the second semiconductor layer SEM2. The passivation layer may be formed of an inorganic layer, for example, a silicon nitride layer, a silicon oxynitride layer, a silicon oxide layer, a titanium oxide layer, and/or an aluminum oxide layer.

The first connection electrode BE1 connects the first electrode E1 of the light emitting element LE to the pixel electrode PXE. The first connection electrode BE1 may be disposed on the top surface and side surface of the first electrode E1 and the top surface of the first semiconductor layer SEM1. The first connection electrode BE1 may be disposed on the passivation layer disposed on one side surface of the first semiconductor layer SEM1, one side surface of the active layer MQW, and at least a portion of one side surface of the second semiconductor layer SEM2. The first connection electrode BE1 may be disposed on a portion of the organic layer 210 disposed between one side surface of the light emitting element LE and the bank 190. The first connection electrode BE1 may be connected to the pixel electrode PXE on the top surface and side surface of the bank 190. That is, the first connection electrode BE1 may be in contact with the pixel electrode PXE on the top surface and side surface of the bank 190.

The second connection electrode BE2 connects the second electrode E2 of the light emitting element LE to the common electrode CE. The second connection electrode BE2 may be disposed on the top surface and one side surface of the second electrode E2. The second connection electrode BE2 may be disposed on another portion of the organic layer 210 disposed between the bank 190 and the other side surface of the light emitting element LE. The other side surface of the light emitting element LE may be a side surface opposite to one side surface of the light emitting element LE. The second connection electrode BE2 may be connected to the common electrode CE on the top surface and side surface of the bank 190. That is, the second connection electrode BE2 may be in contact with the common electrode CE on the top surface and side surface of the bank 190.

FIG. 9A illustrates that the organic layer 210 is disposed on one side surface of the second semiconductor layer SEM2, the top surface of the second portion SEM2_2, and at least a portion of one side surface of the second electrode E2, but the present disclosure is not limited thereto. For example, the organic layer 210 may be disposed on a portion of one side surface of the second semiconductor layer SEM2, and may not be disposed on the top surface of the second portion SEM2_2 of the second semiconductor layer SEM2 and at least a portion of one side surface of the second electrode E2. In this case, the second connection electrode BE2 may be disposed on the top surface of the second portion SEM2_2 of the second semiconductor layer SEM2 and at least a portion of one side surface of the second electrode E2.

The first connection electrode BE1 and the second connection electrode BE2 may include a transparent conductive material (TCO) such as indium tin oxide (ITO) and/or indium zinc oxide (IZO) capable of transmitting light.

The light blocking layer BM may be disposed on the bank 190. The light blocking layer BM may overlap the bank 190 and may not overlap the plurality of light emitting elements LE.

The light blocking layer BM may include a first light blocking layer BM1 and a second light blocking layer BM2 that are sequentially stacked. The length of the first light blocking layer BM1 in the first direction DR1 or the length of the first light blocking layer BM1 in the second direction DR2 may be longer than the length of the second light blocking layer BM2 in the first direction DR1 or the length of the second light blocking layer BM2 in the second direction DR2. The height of the first light blocking layer BM1 may be greater than the height of the second light blocking layer BM2. The first light blocking layer BM1 and the second light blocking layer BM2 may be formed of an organic layer such as acryl resin, epoxy resin, phenolic resin, polyamide resin, polyimide resin, and/or the like. The first light blocking layer BM1 and the second light blocking layer BM2 may include a light blocking material to prevent light of the light emitting element LE of any one sub-pixel from traveling to the neighboring sub-pixel. For example, the first light blocking layer BM1 and the second light blocking layer BM2 may include an organic block pigment or an inorganic black pigment such as carbon black, and/or the like.

The third organic layer 191 may be disposed to cover the light emitting element LE and the organic layer 210 for planarization in the region partitioned by the light blocking layer BM. The third organic layer 191 may be formed of an organic layer such as acryl resin, epoxy resin, phenolic resin, polyamide resin, polyimide resin, and/or the like.

A first light conversion layer QDL1, a second light conversion layer QDL2, and a light transmitting layer TPL may be disposed on the third organic layer 191. The first light conversion layer QDL1, the second light conversion layer QDL2, and the light transmitting layer TPL may be disposed in a region partitioned by the light blocking layer BM. For example, the first light conversion layer QDL1 may be disposed on a first capping layer CAP1 in the first sub-pixel SPX1 and the third sub-pixel SPX3, the second light conversion layer QDL2 may be disposed on the first capping layer CAP1 in the second sub-pixel SPX2, and the light transmitting layer TPL may be disposed on the first capping layer CAP1 in the fourth sub-pixel SPX4.

The first light conversion layer QDL1 may convert a portion of the third light (e.g., light in the blue wavelength band) incident from the light emitting element LE into the first light (e.g., light in the green wavelength band). The first light conversion layer QDL1 may include a first base resin BRS1 and a first wavelength conversion particle WCP1. The first base resin BRS1 may include a light-transmissive organic material. For example, the first base resin BRS1 may include epoxy resin, acrylic resin, cardo resin, and/or imide resin. The first wavelength conversion particle WCP1 may convert a portion of the third light (e.g., light in the blue wavelength band) incident from the light emitting element LE into the first light (e.g., light in the green wavelength band). The first wavelength conversion particle WCP1 may be a quantum dot (QD), a quantum rod, a fluorescent material, and/or a phosphorescent material. The first light conversion layer QDL1 may further include a light diffusion agent such as titanium dioxide (TiO₂).

The second light conversion layer QDL2 may convert a portion of the third light (e.g., light in the blue wavelength band) incident from the light emitting element LE into the second light (e.g., light in the red wavelength band). The second light conversion layer QDL2 may include a second base resin BRS2 and second wavelength conversion particles WCP2. The second base resin BRS2 may include a light-transmissive organic material. For example, the second base resin BRS2 may include epoxy resin, acrylic resin, cardo resin, and/or imide resin. The second wavelength conversion particle WCP2 may convert a portion of the third light (e.g., light in the blue wavelength band) incident from the light emitting element LE into the second light (e.g., light in the red wavelength band). The second wavelength conversion particle WCP2 may be a quantum dot (QD), a quantum rod, a fluorescent material, and/or a phosphorescent material. The second light conversion layer QDL2 may further include a light diffusion agent such as titanium dioxide (TiO₂).

The light transmitting layer TPL may include a light-transmissive organic material. For example, the light transmitting layer TPL may include epoxy resin, acrylic resin, cardo resin, imide resin, and/or the like.

In the present disclosure, a third light conversion layer may be disposed instead of the light transmitting layer TPL. In this case, the third light conversion layer may include a material different from those of the first light conversion layer QDL1 and the second light conversion layer QDL2. For example, the first light conversion layer QDL1 may include quantum dots that convert light in the blue wavelength band into light in the red wavelength band, the second light conversion layer QDL2 may include quantum dots that convert light in the blue wavelength band into light in the green wavelength band, and the third light conversion layer may include blue phosphors. Further, each of the first light conversion layer QDL1, the second light conversion layer QDL2, and the third light conversion layer may include a light dispersing agent such as titanium dioxide (TiO₂) as well as quantum dots. In this case, the number of titanium dioxide (TiO₂) particles in the third light conversion layer may be larger than the number of titanium dioxide (TiO₂) particles in the first light conversion layer QDL1 or the number of titanium dioxide (TiO₂) particles in the second light conversion layer QDL2.

The first capping layer CAP1 may be disposed between the third organic layer 191 and the first light conversion layer QDL1, between the third organic layer 191 and the second light conversion layer QDL2, between the third organic layer 191 and the light transmitting layer TPL, between the light blocking layer BM and the first light conversion layer QDL1, between the light blocking layer BM and the second light conversion layer QDL2, and between the light blocking layer BM and the light transmitting layer TPL. The first capping layer CAP1 may be formed of an inorganic layer, for example, a silicon nitride layer, a silicon oxynitride layer, a silicon oxide layer, a titanium oxide layer, and/or an aluminum oxide layer. The first capping layer CAP1 may be disposed on the top surface of the light blocking layer BM.

A reflection layer RF may be disposed between the light blocking layer BM and the first light conversion layer QDL1, between the light blocking layer BM and the second light conversion layer QDL2, and between the light blocking layer BM and the light transmitting layer TPL. The reflection layer RF may be disposed on the first capping layer CAP1 disposed on the side surface of the first light blocking layer BM1 and the side surface of the second light blocking layer BM2. The reflection layer RF serves to reflect light traveling in the lateral direction from the first light conversion layer QDL1, the second light conversion layer QDL2, and the light transmitting layer TPL.

The reflection layer RF may include a metal material having high reflectivity, such as aluminum (Al). The thickness of the reflection layer RF may be about 0.1 μm.

Alternatively, the reflection layer RF may include M (M being an integer of 2 or more) pairs of first layers and second layers having different refractive indices to serve as a distributed Bragg reflector (DBR). In this case, M first layers and M second layers may be disposed alternately. The first layer and the second layer may be formed of an inorganic layer, for example, a silicon nitride layer, a silicon oxynitride layer, a silicon oxide layer, a titanium oxide layer, and/or an aluminum oxide layer.

The second capping layer CAP2 may be disposed on the first capping layer CAP1, the first light conversion layer QDL1, the second light conversion layer QDL2, and the light transmitting layer TPL. The second capping layer CAP2 may be formed of an inorganic layer, for example, a silicon nitride layer, a silicon oxynitride layer, a silicon oxide layer, a titanium oxide layer, and/or an aluminum oxide layer.

The first capping layer CAP1 and the second capping layer CAP2 serve to protect the first wavelength conversion particles WCP1 of the first light conversion layer QDL1 and the second wavelength conversion particles WCP2 of the second light conversion layer QDL2 from moisture or oxygen, so that the first light conversion layer QDL1, the second light conversion layer QDL2, and the light transmitting layer TPL may be encapsulated by the first capping layer CAP1 and the second capping layer CAP2.

In addition, the first capping layer CAP1 and the second capping layer CAP2 may be formed of a low refractive index material with a lower refractive index than the fourth organic layer 192, and in this case, the total reflection of light converted in the first light conversion layer QDL1 or the second light conversion layer QDL2 may be prevented or minimized in the first capping layer CAP1 and the second capping layer CAP2. Accordingly, the light converted in the first light conversion layer QDL1 or the second light conversion layer QDL2 may be condensed on the top of the first light conversion layer QDL1 or the second light conversion layer QDL2. For example, the refractive index of at least one of the first capping layer CAP1 or the second capping layer CAP2 may be approximately 1.1 to 1.5, and the refractive index of each of the first base resin BRS1 of the first light conversion layer QDL1, the second base resin BRS2 of the second light conversion layer QDL2, and the light transmitting layer TPL may be approximately 1.5 to 2.0.

Alternatively, a fourth organic layer 192 may also be formed of a low refractive index material, and in this case, the total reflection of the light, which is converted in the first light conversion layer QDL1 or the second light conversion layer QDL2, by the fourth organic layer 192 may be prevented or minimized. Accordingly, the light converted in the first light conversion layer QDL1 or the second light conversion layer QDL2 may be condensed on the top of the first light conversion layer QDL1 or the second light conversion layer QDL2.

The fourth organic layer 192 may be disposed on the second capping layer CAP2. The fourth organic layer 192 may be formed of acryl resin, epoxy resin, phenolic resin, polyamide resin, polyimide resin, and/or the like.

When the light emitting elements LE of the first sub-pixel SPX1, the light emitting elements LE of the second sub-pixel SPX2, and the light emitting elements LE of the third sub-pixel SPX3 emit light in the blue wavelength band, the first light conversion layer QDL1 and the second light conversion layer QDL2 are required for wavelength conversion. However, the present disclosure is not limited thereto, and when the light emitting elements LE of the first sub-pixel SPX1 emit light of the first color, the light emitting elements LE of the second sub-pixel SPX2 emit light of a second color, and the light emitting elements LE of the third sub-pixel SPX3 emit light of a third color, the first light conversion layer QDL1, the second light conversion layer QDL2, and the light transmitting layer TPL may be omitted.

Alternatively, when the light emitting elements LE of the first sub-pixel SPX1 emit light of the first color, the light emitting elements LE of the second sub-pixel SPX2 emit light of the second color, and the light emitting elements LE of the third sub-pixel SPX3 emit light of the third color, phosphor particles may be included to increase color purity instead of wavelength conversion particles.

A plurality of color filters CF1, CF2, and CF3 may be disposed on the fourth organic layer 192. The plurality of color filters CF1, CF2 and CF3 may include first color filters CF1, second color filters CF2, and third color filters CF3.

The first color filter CF1 disposed in the first sub-pixel SPX1 and the third sub-pixel SPX3 may transmit the first light (e.g., light in the green wavelength band), and may absorb or block the third light (e.g., light in the blue wavelength band). Therefore, the first color filter CF1 may transmit the first light (e.g., light in the green wavelength band) converted by the first light conversion layer QDL1 from among the third light (e.g., light in the blue wavelength band) emitted from the light emitting element LE, and may absorb or block the third light (e.g., light in the blue wavelength band) that is not converted by the first light conversion layer QDL1. Accordingly, the first sub-pixel SPX1 may emit the first light (e.g., light in the green wavelength band).

The second color filter CF2 disposed in the second sub-pixel SPX2 may transmit the second light (e.g., light in the red wavelength band), and may absorb or block the third light (e.g., light in the blue wavelength band). Therefore, the second color filter CF2 may transmit the second light (e.g., light in the red wavelength band) converted by the first light conversion layer QDL1 from among the third light (e.g., light in the blue wavelength band) emitted from the light emitting element LE, and may absorb or block the third light (e.g., light in the blue wavelength band) that is not converted by the first light conversion layer QDL1. Accordingly, the second sub-pixel SPX2 may emit the second light (e.g., light in the red wavelength band).

The third color filter CF3 disposed in the fourth sub-pixel SPX4 may transmit third light (e.g., light in the blue wavelength band). Accordingly, the third color filter CF3 may transmit the third light (e.g., light in the blue wavelength band) passing through the light transmitting layer TPL and emitted from the light emitting element LE. Accordingly, the fourth sub-pixel SPX4 may emit the third light (e.g., light in the blue wavelength band).

The area in which the first color filter CF1, the second color filter CF2, and the third color filter CF3 overlap may serve to block light. The area in which the first color filter CF1, the second color filter CF2, and the third color filter CF3 overlap may overlap the bank 190 and the light blocking layer BM.

A fifth organic layer 193 for planarization may be disposed on the plurality of color filters CF1, CF2, and CF3. The fifth organic layer 193 may be formed of acryl resin, epoxy resin, phenolic resin, polyamide resin, polyimide resin, and/or the like.

According to FIGS. 8 and 9A, both the first electrode E1 and the second electrode E2 of the light emitting element LE are disposed on the top surface of the light emitting element LE, so that the current of the light emitting element LE flows through the first electrode E1, the first semiconductor layer SEM1, the active layer MQW, a first portion SEM2_1 of the second semiconductor layer SEM2, a second portion SEM2_2 of the second semiconductor layer SEM2, and the second electrode E2. Accordingly, because the current of the light emitting element LE does not flow through the undoped semiconductor layer USEM, it is possible to reduce or prevent the luminous efficiency of the micro light emitting element from decreasing or the micro light emitting element from not emitting light due to the resistance of the undoped semiconductor layer USEM.

In addition, in each of the sub-pixels SPX1 to SPX4, the organic layer 210 is disposed on the pixel electrode PXE and the common electrode CE, the light emitting element LE is disposed on the organic layer 210, the first electrode E1 of the light emitting element LE is connected to the pixel electrode PXE by using the first connection electrode BE1, and the second electrode E2 of the light emitting element LE is connected to the common electrode CE by using the second connection electrode BE2. Accordingly, in the process of transferring the plurality of light emitting elements LE to the display panel 100 by using the organic layer 210, the plurality of light emitting elements LE may be temporarily fixed or adhered. In addition, despite the organic layer 210 for temporary adhesion, the first electrode E1 of the light emitting element LE may be electrically connected to the pixel electrode PXE, and the second electrode E2 of the light emitting element LE may be electrically connected to the common electrode CE.

In addition, when the plurality of light emitting elements LE are adhered to the bonding electrode disposed on each of the plurality of pixel electrodes PXE by using eutectic bonding, which is adhered by heat and pressure, the bonding electrode of each of the plurality of light emitting elements LE and the bonding electrode of each of the plurality of pixel electrodes PXE are required to be accurately aligned, so that when the alignment deviates, it may lead to a defect in which the light emitting element LE does not light up. In contrast, in the present disclosure, each of the plurality of light emitting elements LE is only required be disposed on the organic layer 210 for temporary adhesion at the opening OA defined by the bank 190, so that it does not require alignment accuracy as in the case when adhesion is performed by eutectic bonding.

In addition, in the case of eutectic bonding, heat and pressure are required to adhere the bonding electrode of each of the plurality of light emitting elements LE to the bonding electrode of each of the pixel electrodes PXE, but the light emitting element LE may be tilted or damaged by heat and pressure. In contrast, in the present disclosure, because heat and pressure are not required, the light emitting element LE is not tilted or damaged by heat and pressure. Although the third sub-pixel SPX3 is not illustrated in FIG. 8, the third sub-pixel SPX3 may be formed substantially the same as the first sub-pixel SPX1. Therefore, description of the third sub-pixel SPX3 is omitted.

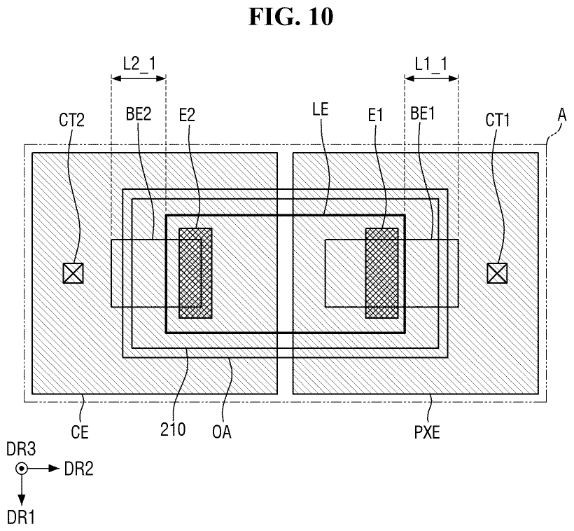

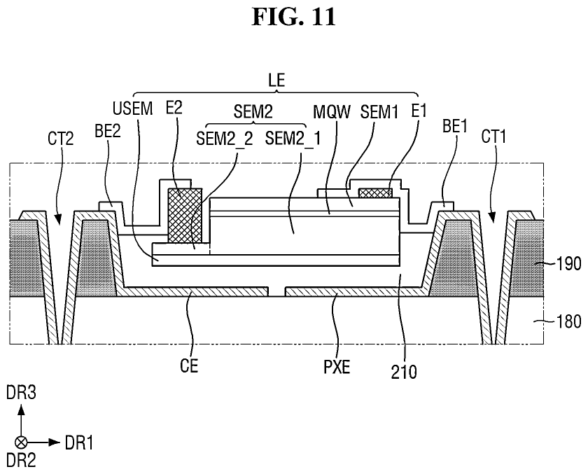

FIG. 10 is a layout view illustrating another example of the area A of FIG. 6 in detail. FIG. 11 is a cross-sectional view showing an example of a cross section of a light emitting element corresponding to the line I3-I3′ of FIG. 6.

The embodiment of FIGS. 10 and 11 differs from the embodiment of FIGS. 7 and 9A in that a distance L1_1 from the light emitting element LE to one end of the first connection electrode BE1 and a distance L2_1 from the light emitting element LE to one end of the second connection electrode BE2 are smaller than of the distances L1 and L2 of the embodiment of FIGS. 7 and 9A. In the embodiment of FIGS. 10 and 11, redundant parts of the description with reference to FIGS. 7 and 9A will be omitted.

Referring to FIGS. 7, 9A, 10, and 11, the distances L1 and L1_1 from the light emitting element LE to one end of the first connection electrode BE1 may be adjusted to suit the size of each of the sub-pixels SPX1, SPX2, SPX3 and SPX4. For example, as illustrated in FIGS. 7 and 9A, when the number of pixels PX per unit area is small and the size of each of the sub-pixels SPX1, SPX2, SPX3, and SPX4 is large, the distance L1 from the light emitting element LE to one end of the first connection electrode BE1 may increase. In contrast, as illustrated in FIGS. 10 and 11, when the number of pixels PX per unit area is large and the size of each of the sub-pixels SPX1, SPX2, SPX3, and SPX4 is small, the distance L1_1 from the light emitting element LE to one end of the first connection electrode BE1 may decrease. One end of the first connection electrode BE1 may be a portion in contact with the pixel electrode PXE.

In addition, the distances L2 and L2_1 from the light emitting element LE to one end of the second connection electrode BE2 may be adjusted to suit the size of each of the sub-pixels SPX1, SPX2, SPX3 and SPX4. For example, as illustrated in FIGS. 7 and 9A, when the number of pixels PX per unit area is small and the size of each of the sub-pixels SPX1, SPX2, SPX3, and SPX4 is large, the distance L2 from the light emitting element LE to one end of the second connection electrode BE2 may increase. In contrast, as illustrated in FIGS. 10 and 11, when the number of pixels PX per unit area is large and the size of each of the sub-pixels SPX1, SPX2, SPX3, and SPX4 is small, the distance L2_2 from the light emitting element LE to one end of the second connection electrode BE2 may decrease. One end of the second connection electrode BE2 may be a portion in contact with the common electrode CE.

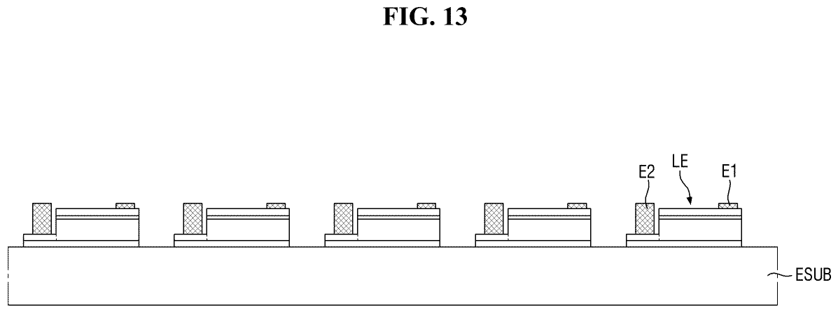

FIG. 12 is a flowchart illustrating a method for manufacturing a display device according to one or more embodiments. FIGS. 13-19 are cross-sectional views illustrating a method for manufacturing a display device according to one or more embodiments. FIGS. 13-19 illustrate examples of cross sections of the display panel corresponding to the lines I1-I1′, I2-I2′, and I3-I3′ in FIG. 6.

First, as illustrated in FIG. 13, the plurality of light emitting elements LE disposed on a light emitting element substrate ESUB are prepared (step S110 in FIG. 12).

The plurality of light emitting elements LE are disposed on a fourth adhesive layer disposed on the light emitting element substrate ESUB. The plurality of light emitting elements LE are adhered and fixed to the fourth adhesive layer. The light emitting element substrate ESUB may include a material that allows light to pass therethrough. For example, a first support layer may include a transparent polymer such as polyimide, polyester, polyacrylic, polyepoxy, polyethylene, polystyrene, polyethylene terephthalate, and/or the like. The fourth adhesive layer may include an adhesive material for adhering the plurality of light emitting elements LE. For example, the adhesive material may include urethane acrylates, epoxy acrylates, polyester acrylates, and/or the like.

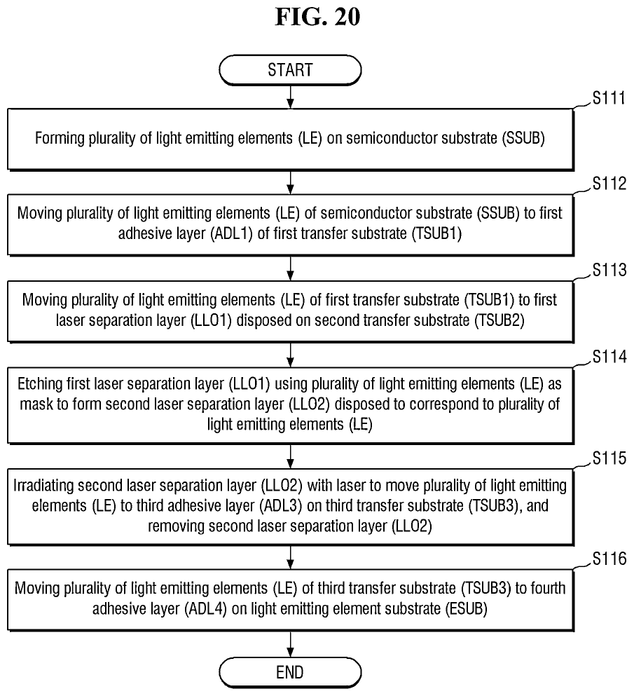

A detailed description of a method of moving the plurality of light emitting elements LE formed on the semiconductor substrate SSUB onto the light emitting element substrate ESUB will be described later with reference to FIGS. 20-26.

Second, the thin film transistor layer TFTL is formed on the substrate SUB, and the bank 190, the pixel electrodes PXE, and the common electrodes CE are formed on the thin film transistor layer TFTL by using a mask (step S120 in FIG. 12).

The barrier layer BR is formed on the substrate SUB, and the first channel regions CHA1, the first source regions S1, and the first drain regions D1 of the first thin film transistors TFT1 are formed on the barrier layer BR using a photolithography process.

Then, the first gate insulating layer 131 is formed on the first channel regions CHA1, the first source regions S1, and the first drain regions D1 of the first thin film transistors TFT1, and the barrier layer, and the first gate electrodes G1 and the first capacitor electrodes CAE1 of the first thin film transistors TFT1 are formed on the first gate insulating layer 131. The first channel regions CHA1, the first source regions S1, and the first drain regions D1 of the first thin film transistors TFT1 may include polycrystalline silicon, monocrystalline silicon, low-temperature polycrystalline silicon, and/or amorphous silicon.

Then, the second gate insulating layer 132 is formed on the first gate insulating layer 131, the first gate electrodes G1 of the first thin film transistors TFT1, and the first capacitor electrodes CAE1, and the second capacitor electrodes CAE2 are formed on the second gate insulating layer 132 using a photolithography process.

Then, the first interlayer insulating layer 141 is formed on the second gate insulating layer 132, the second capacitor electrodes CAE2, and the second channel regions CHA2, the second source regions S2, and the second drain regions D2 of the second thin film transistors TFT2 are formed on the first interlayer insulating layer 141 using a photolithography process. The second channel regions CHA2, the second source regions S2, and the second drain regions D2 of the second thin film transistors TFT2 may include an oxide semiconductor including indium (In), gallium (Ga), and/or oxygen (O).

Then, the third gate insulating layer 133 is formed on the first interlayer insulating layer 141, the second channel regions CHA2, the second source regions S2, and the second drain regions D2 of the second thin film transistors TFT2, and the second gate electrodes G2 of the second thin film transistors TFT2 are formed on the third gate insulating layer 133 using a photolithography process.

Then, the second interlayer insulating layer 142 is formed on the third gate insulating layer 133, the second gate electrodes G2 of the second thin film transistors TFT2. Further, the first source connection hole PCT1 penetrating the first gate insulating layer 131, the second gate insulating layer 132, the first interlayer insulating layer 141, the third gate insulating layer 133, and the second interlayer insulating layer 142, the second source connection hole BCT1 penetrating the second interlayer insulating layer 142 and the third gate insulating layer 133, and the third source connection hole BCT2 penetrating the second interlayer insulating layer 142 and the third gate insulating layer 133 are formed using a photolithography process. Further, the first source connection electrodes PCE1, the second source connection electrodes SBE1, and the third source connection electrodes SBE2 are formed on the second interlayer insulating layer 142 using a photolithography process.

Then, the first organic layer 160 is formed on the second interlayer insulating layer 142, the first source connection electrodes PCE1, the second source connection electrodes SBE1, and the third source connection electrodes SBE2, and the first connection holes CT1 and the second connection holes CT2 exposing the fourth source connection electrodes PCE2 and the second power lines VSL are formed on the first organic layer 160 by using a photolithography process. In addition, the pixel electrodes PXE and the common electrodes CE disposed on the second organic layer 180 and the bank 190 are formed using a photolithography process. Each of the pixel electrodes PXE is disposed in the corresponding first connection hole CT1, and the common electrodes CE respectively disposed in the second connection holes CT2 and the disposed pixel electrodes PXE are formed.

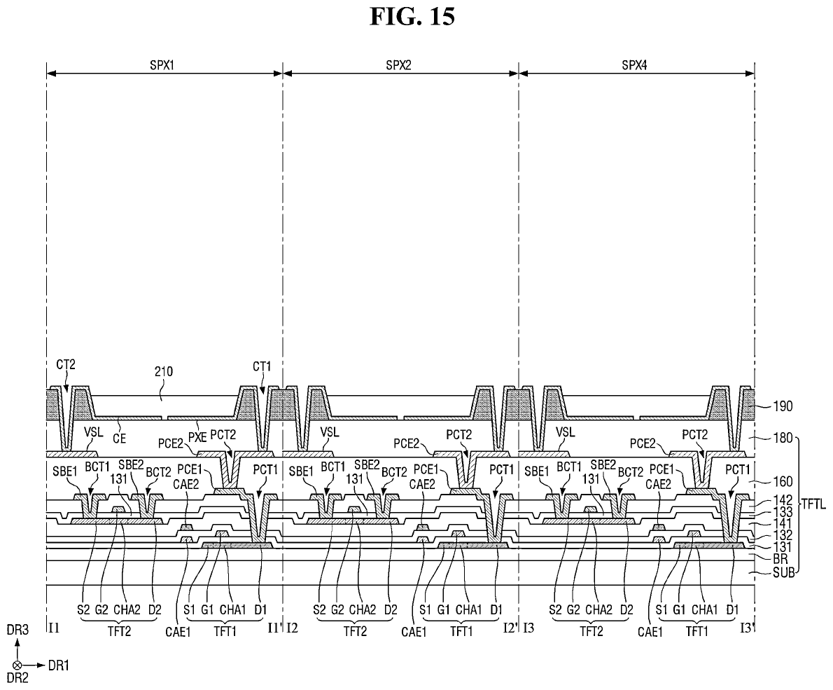

Third, as illustrated in FIG. 15, the organic layer 210 is formed on the pixel electrodes PXE and the common electrode CE in the opening OA (step S130 in FIG. 32).

The organic layer 210 may be a temporary adhesive layer, a short-term adhesive layer, and/or a temporary pinned layer that serves to temporarily fix or adhere the plurality of the light emitting elements LE in the process of transferring the plurality of light emitting elements LE to the display panel 100. The thickness of the organic layer 210 may be smaller than the height of the opening OA or the thickness of the bank 190.

The organic layer 210 may be a photosensitive organic layer such as a photoresist. Alternatively, the organic layer 210 may be formed of acryl resin, epoxy resin, phenolic resin, polyamide resin, polyimide resin, and/or the like.

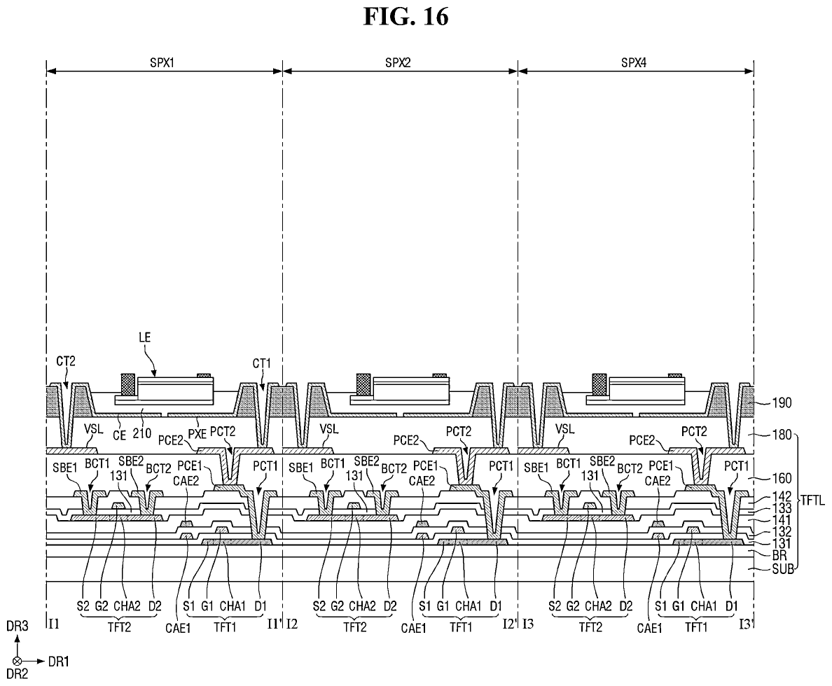

Fourth, as illustrated in FIG. 16, the plurality of light emitting elements LE of the light emitting element substrate ESUB are fixed to the organic layer 210 by using a stamp (step S140 in FIG. 12).

A stamp may include an adhesive layer that has a higher thickness than the fourth adhesive layer of the light emitting element substrate ESUB and may detach the plurality of light emitting elements LE from the fourth adhesive layer. Each of the plurality of light emitting elements LE that are detached from the light emitting element substrate ESUB and transferred to the stamp may be embedded and temporarily fixed in the organic layer 210. At this time, a portion of each of the plurality of light emitting elements LE may be embedded and temporarily fixed in the organic layer 210. For example, the undoped semiconductor layer USEM of each of the plurality of light emitting elements LE may be embedded and fixed in the organic layer 210.

When the organic layer 210 is a photosensitive organic layer such as a photoresist, after hardening (e.g., soft baking) the organic layer 210 at a first temperature, at least a portion of each of the plurality of light emitting elements LE is embedded in the organic layer 210. Then, the organic layer 210 may be completely cured at a second temperature higher than the first temperature. The first temperature may be approximately 100 degrees, and the second temperature may be approximately 230 degrees, but the present disclosure is not limited thereto. In the process of curing the organic layer 210 at the first temperature, because the first temperature is too low to completely cure the organic layer 210, the organic layer 210 may have fluidity, and thus the organic layer 210 may spread throughout the opening OA. In addition, the process of completely curing the organic layer 210 at the second temperature may be performed for approximately 30 minutes.

Alternatively, because at least a portion of the light emitting element LE is inserted and embedded in the organic layer 210, the organic layer 210 may remain between the bottom surface of the light emitting element LE and the pixel electrode PXE and between the bottom surface of the light emitting element LE and the common electrode CE.

Alternatively, when the fluidity of the organic layer 210 is high, the organic layer 210 may be pushed to the edge of the opening OA by the light emitting element LE, and in this case, the organic layer 210 may be removed between the bottom surface of the light emitting element LE and the pixel electrode PXE and between the bottom surface of the light emitting element LE and the common electrode CE, or the organic layer 210 with a very small height may be disposed. That is, the organic layer 210 may not be disposed between the bottom surface of the light emitting element LE and the pixel electrode PXE or between the bottom surface of the light emitting element LE and the common electrode CE, or may be disposed with a very small height.

Alternatively, when the fluidity of the organic layer 210 is small or the organic layer 210 is hard, the depth at which the light emitting element LE is inserted or embedded in the organic layer 210 is very small, or the light emitting element LE may be disposed on the organic layer 210 without being inserted or embedded in the organic layer 210.

Then, by applying heat to the adhesive layer of the stamp to lower the thickness of the adhesive layer, the stamp may be separated from the plurality of light emitting elements LE.

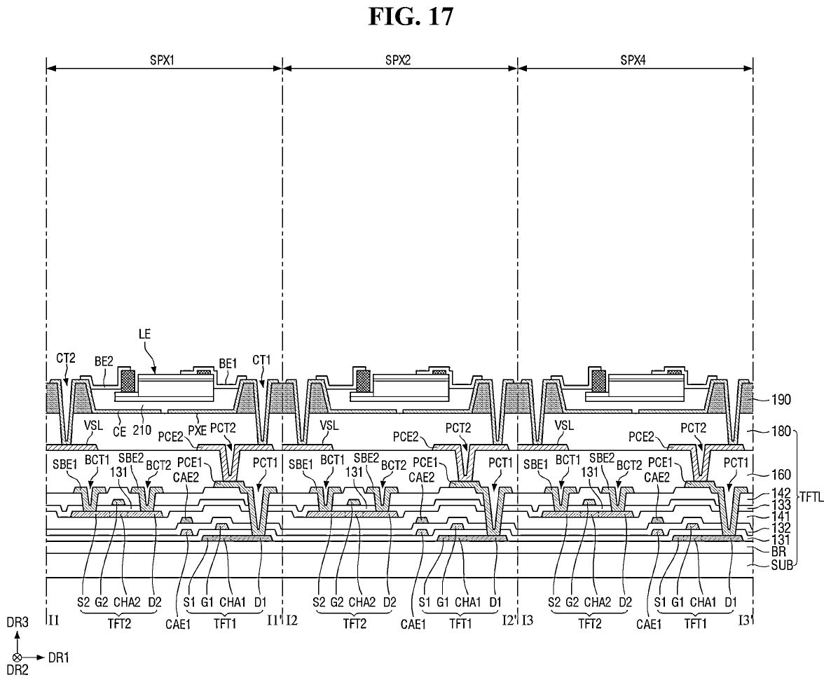

Fifth, as illustrated in FIG. 17, the first connection electrodes BE1 and the second connection electrodes BE2 are formed using a photolithography process (step S150 in FIG. 12).

The first connection electrode BE1 connects the first electrode E1 of the light emitting element LE disposed on the organic layer 210 to the pixel electrode PXE in each of the sub-pixels SPX1 to SPX4. The second connection electrode BE2 connects the second electrode E2 of the light emitting element LE to the common electrode CE in each of the sub-pixels SPX1 to SPX4.

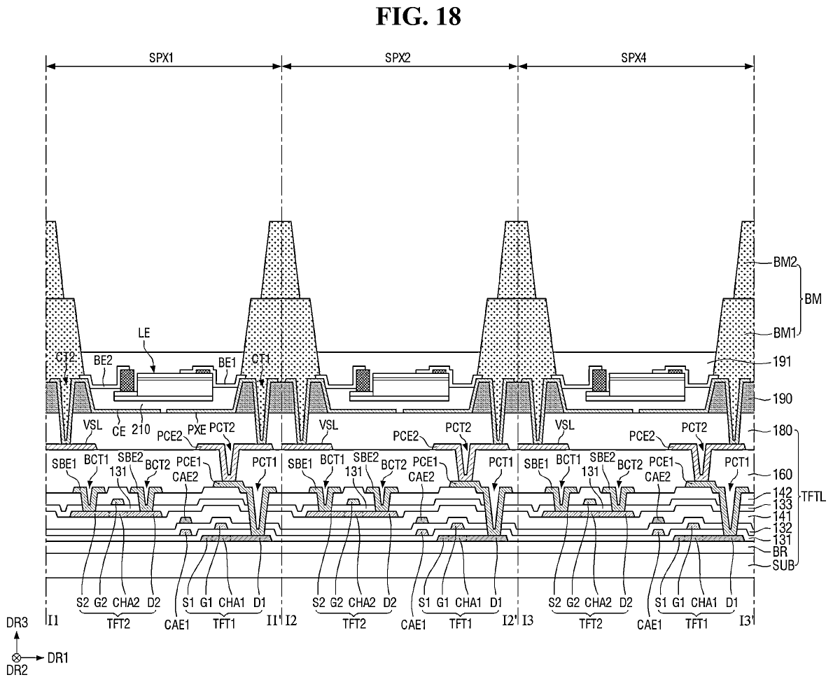

Sixth, as illustrated in FIG. 18, the light blocking layer BM and the third organic layer 191 are sequentially formed (step S160 in FIG. 12).

The first light blocking layer BM1 of the light blocking layer BM may be formed on the bank 190, and the second light blocking layer BM2 of the light blocking layer BM may be formed on the first light blocking layer BM1.

FIG. 18 is an example that shows a stepped portion is formed extending to the side surface of the first light blocking layer BM1, a portion of the top surface of the first light blocking layer BM1, and the side surface of the second light blocking layer BM2 because the length of the bottom surface of the second light blocking layer BM2 in the first direction DR1 is shorter than the length of the top surface of the first light blocking layer BM1 in the first direction DR1, but the present specification is not limited thereto. For example, the length of the bottom surface of the second light blocking layer BM2 in the first direction DR1 may be substantially the same as the length of the top surface of the first light blocking layer BM1 in the first direction DR1, and accordingly, the side surface of the first light blocking layer BM1 and the side surface of the second light blocking layer BM2 may be connected without the stepped portion. Alternatively, the length of the bottom surface of the second light blocking layer BM2 in the first direction DR1 may be substantially the same as the length of the top surface of the first light blocking layer BM1 in the first direction DR1, but the angle at which the side surface of the first light blocking layer BM1 is inclined relative to the bottom surface of the first light blocking layer BM1 may be different from the angle at which the side surface of the second light blocking layer BM2 is inclined relative to the bottom surface of the second light blocking layer BM2. When the stepped portion is reduced or removed, it is possible to prevent or minimize the occurrence of uneven light reflection such as light leakage due to diffuse reflection of light. The third organic layer 191 may be formed to cover the light emitting element LE in a region partitioned by the light blocking layer BM.

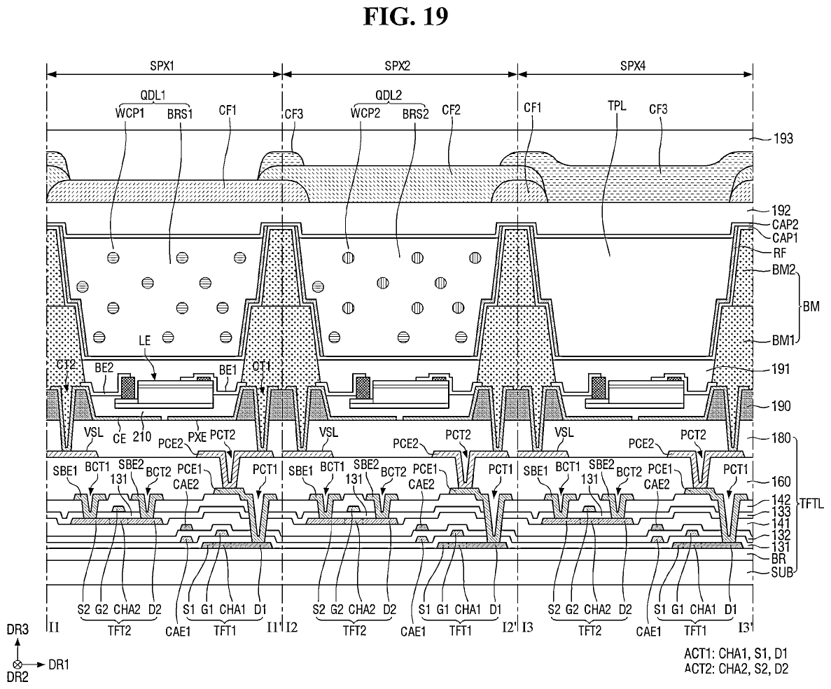

Seventh, as illustrated in FIG. 19, in the region partitioned by the light blocking layer BM, the first light conversion layer QDL1, the second light conversion layer QDL2, and the light transmitting layer TPL are formed on the third organic layer 191, and the color filters CF1, CF2, and CF3 are formed on the first light conversion layer QDL1, the second light conversion layer QDL2, and the light transmitting layer TPL (step S170 in FIG. 12).

First, the first capping layer CAP1 that covers the third organic layer 191 and the light blocking layer BM is formed, and the reflection layer RF is formed on the first capping layer CAP1 disposed on the side surface of the light blocking layer BM.

Then, from among the regions partitioned from the light blocking layer BM, the first light conversion layer QDL1 is formed in the region corresponding to the first sub-pixel SPX1, the second light conversion layer QDL2 is formed in the region corresponding to the second sub-pixel SPX2, and the light transmitting layer TPL is formed in the region corresponding to the fourth sub-pixel SPX4.

Then, the second capping layer CAP2 is formed on the first capping layer CAP1, the first light conversion layer QDL1, the second light conversion layer QDL2, and the light transmitting layer TPL, and the fourth organic layer 192 is formed on the second capping layer CAP2.

Then, the plurality of color filters CF1, CF2, and CF3 are formed on the fourth organic layer 192, and the fifth organic layer 193 is formed on the plurality of color filters CF1, CF2, and CF3.

As illustrated in FIGS. 12-19, in each of the sub-pixels SPX1 to SPX4, the organic layer 210 may be formed on the pixel electrode PXE and the common electrode CE, and the light emitting element LE may be fixed to the organic layer 210 by disposing a portion of the light emitting element LE to be embedded in the organic layer 210 and then completely curing the organic layer 210. Accordingly, in the process of transferring the plurality of light emitting elements LE to the display panel 100, each of the plurality of light emitting elements LE may be easily fixed.

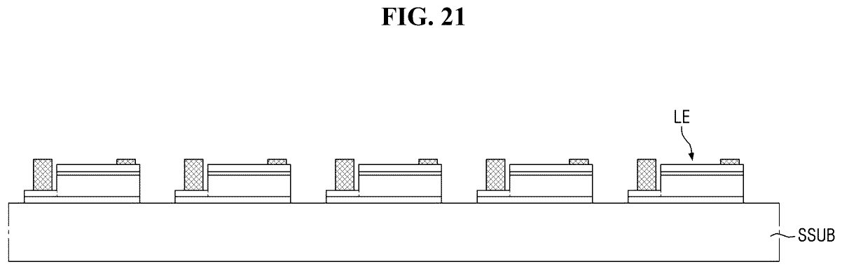

FIG. 20 is a flowchart showing step S110 of FIG. 12 in detail. FIGS. 21-27 are cross-sectional views for explaining step S110.

Hereinafter, with reference to FIGS. 20-26, the process of moving the plurality of light emitting elements LE formed on the semiconductor substrate SSUB to the light emitting element substrate ESUB will be described in detail.

First, the plurality of light emitting elements LE are formed on the semiconductor substrate SSUB as illustrated in FIG. 21 (step S111 in FIG. 20).

The semiconductor substrate SSUB may be a silicon wafer substrate or a sapphire substrate. A light emitting element material layer is deposited on the entire surface of the semiconductor substrate SSUB. The light emitting element material layer may be formed through an epitaxial growth process on the semiconductor substrate SSUB. As an epitaxial growth process, a method of forming the light emitting element material layer may include electron beam deposition, physical vapor deposition (PVD), chemical vapor deposition (CVD), plasma laser deposition (PLD), dual-type thermal evaporation, sputtering, metal organic chemical vapor deposition (MOCVD), and/or the like. Preferably, metal organic chemical vapor deposition (MOCVD) may be used, but the present disclosure is not limited thereto. As illustrated in FIG. 9A, the light emitting element material layer may include the undoped semiconductor layer USEM, the second semiconductor layer SEM2, the active layer MQW, and the first semiconductor layer SEM1.

Then, after forming a mask pattern on the light emitting element material layer, the light emitting element material layer may be etched according to the mask pattern to form the plurality of light emitting elements LE. The mask pattern may be removed after forming the plurality of light emitting elements LE.

The light emitting element material layer may be etched by a dry etching method, a wet etching method, a reactive ion etching (RIE) method, a deep reactive ion etching (DRIE) method, an inductively coupled plasma reactive ion etching (ICP-RIE) method, and/or the like. The dry etching method may be suitable for vertical etching because anisotropic etching can be performed. When using a dry etching method, the etching gas may be Cl₂ or O₂, but is not limited thereto.

Then, the first electrode E1 is formed on the first semiconductor layer SEM1 in each of the plurality of light emitting elements LE, and the second electrode E2 is formed on the second portion SEM2_2 of the second semiconductor layer SEM2. In order to compensate for the thickness difference between the first portion SEM2_1 and the second portion SEM2_2 of the second semiconductor layer SEM2, the thickness of the active layer MQW, and the thickness of the first semiconductor layer SEM1, the thickness of the second electrode E2 may be greater than the thickness of the first electrode E1. For example, the thickness of the second electrode E2 may be more than the sum of the thickness difference between the first portion SEM2_1 and the second portion SEM2_2 of the second semiconductor layer SEM2, the thickness of the active layer MQW, and the thicknesses of the first semiconductor layer SEM1.

Then, the passivation layer covering the side surfaces of the first semiconductor layer SEM1, the active layer MQW, the second semiconductor layer SEM2, and the undoped semiconductor layer USEM in each of the plurality of light emitting elements LE may be formed.

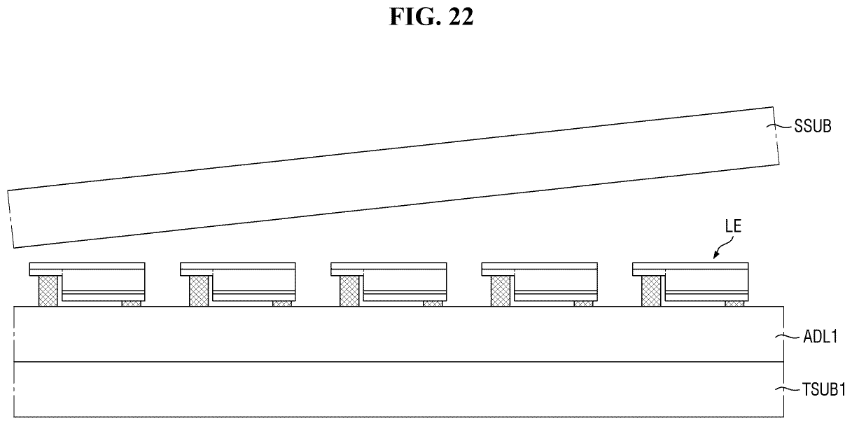

Second, as illustrated in FIG. 22, the plurality of light emitting elements LE of the semiconductor substrate SSUB are moved to the first adhesive layer ADL1 disposed on a first transfer substrate TSUB1 (step S112 in FIG. 20).

The first transfer substrate TSUB1 may be made of a transparent material to allow light to pass therethrough. For example, the first transfer substrate TSUB1 may include a transparent polymer such as polyimide, polyester, polyacrylic, polyepoxy, polyethylene, polystyrene, polyethylene terephthalate, and/or the like. The first adhesive layer ADL1 disposed on one surface of the first transfer substrate TSUB1 may include an adhesive material for adhering the plurality of light emitting elements LE. For example, the adhesive material may include urethane acrylates, epoxy acrylates, polyester acrylates, and/or the like.

The first electrode E1 and the second electrode E2 of each of the plurality of light emitting elements LE may be adhered to the first adhesive layer ADL1 disposed on the first transfer substrate TSUB1. Then, the plurality of light emitting elements LE may be separated from the semiconductor substrate SSUB through a laser lift off (LLO) process in which a laser is irradiated to the semiconductor substrate SSUB. The laser may be a KrF excimer laser with a wavelength of approximately 248 nm, but the present disclosure is not limited thereto.

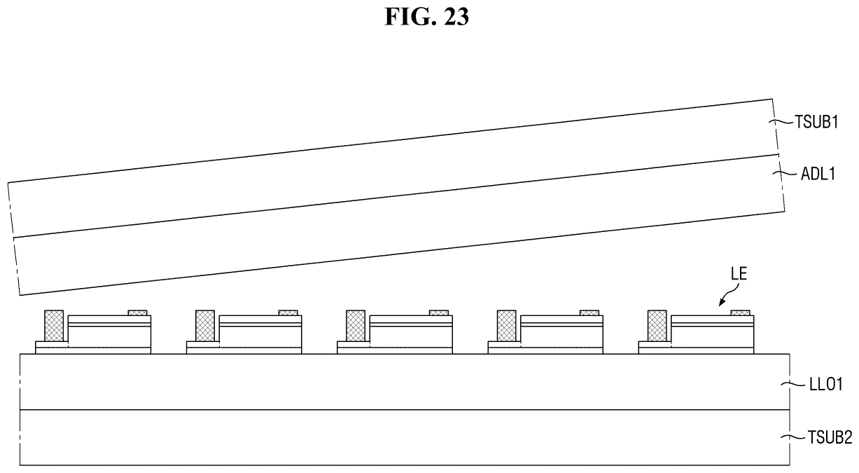

Third, as illustrated in FIG. 23, the plurality of light emitting elements LE of the first transfer substrate TSUB1 are moved to a first laser separation layer LLO1 disposed on a second transfer substrate TSUB2 (step S113 in FIG. 20).

The second transfer substrate TSUB2 may be made of a transparent material to allow light to pass therethrough. For example, the second transfer substrate TSUB2 may include a transparent polymer such as polyimide, polyester, polyacrylic, polyepoxy, polyethylene, polystyrene, polyethylene terephthalate, and/or the like. The first laser separation layer LLO1 disposed on the second transfer substrate TSBU2 may be a layer that may be separated by laser irradiation, and may include, for example, a transparent polymer such as polyimide.

When heat is applied in a state in which one surface of each of the plurality of light emitting elements LE is in contact with the first laser separation layer LLO1, each of the plurality of light emitting elements LE may be adhered or fixed to the first laser separation layer LLO1, and as the tackiness of the first adhesive layer ADL1 weakens, each of the plurality of light emitting elements LE may be separated from the first adhesive layer ADL1. One surface of each of the plurality of light emitting elements LE may be an opposite surface of the other surface on which the first electrode E1 and the second electrode E2 are disposed at each of the plurality of the light emitting elements LE.

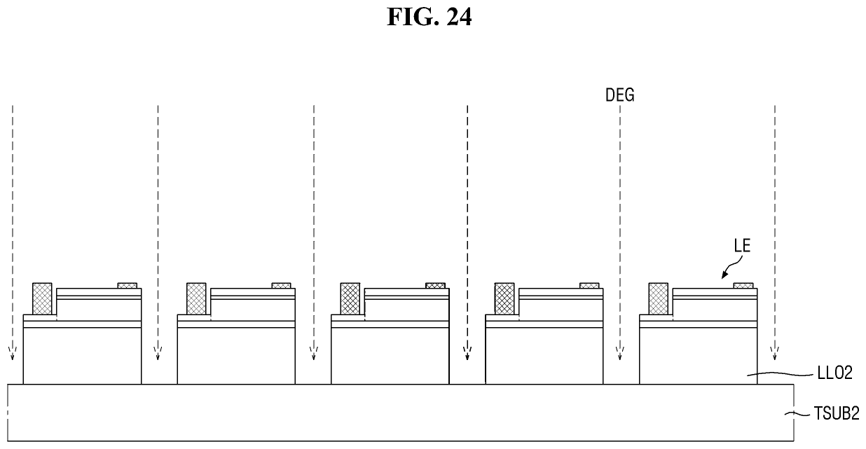

Fourth, as illustrated in FIG. 24, the first laser separation layer LLO1 is etched using the plurality of light emitting elements LE as a mask, and a second laser separation layer LLO2 disposed to correspond to the plurality of light emitting elements LE is formed (step S114 in FIG. 20).

The plurality of light emitting elements LE are not etched, but are dry-etched using etching gas DEG in which only the first laser separation layer LLO1 is etched. That is, the first laser separation layer LLO1 is etched using the plurality of light emitting elements LE as a mask. Accordingly, the first laser separation layer LLO1 that does not overlap the plurality of light emitting elements LE in the thickness direction of the second transfer substrate TSUB2 may be removed. Accordingly, the second laser separation layer LLO2 that overlaps the plurality of light emitting elements LE in the thickness direction of the second transfer substrate TSUB2 may be formed. The second laser separation layer LLO2 may be disposed between each of the plurality of light emitting elements LE and the second transfer substrate TSUB2 in the thickness direction of the second transfer substrate TSUB2.

When the second laser separation layer LLO2 is not separated for each of the plurality of light emitting elements LE, at the time of selectively transferring some of the light emitting elements LE from among the plurality of light emitting elements LE in the subsequent process, the laser shock that occurs between some of the light emitting elements LE and the second laser separation layer LLO2 that are irradiated with the laser may propagate between the remaining light emitting elements LE and the second laser separation layer LLO2. In this case, during the process of selectively transferring some of the light emitting elements LE, some of the remaining light emitting elements LE may fall off from the second laser separation layer LLO2.

However, in the present disclosure, the second laser separation layer LLO2 may be separated for each of the plurality of light emitting elements LE, so that it is possible to prevent the laser shock that occurs between some of the light emitting elements LE and the second laser separation layer LLO2 that are irradiated with the laser in the subsequent process from propagating between the remaining light emitting elements LE and the second laser separation layer LLO2.

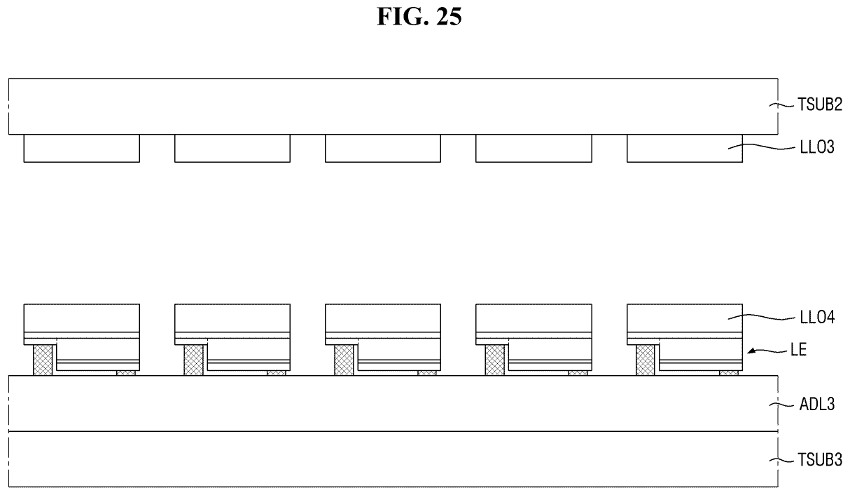

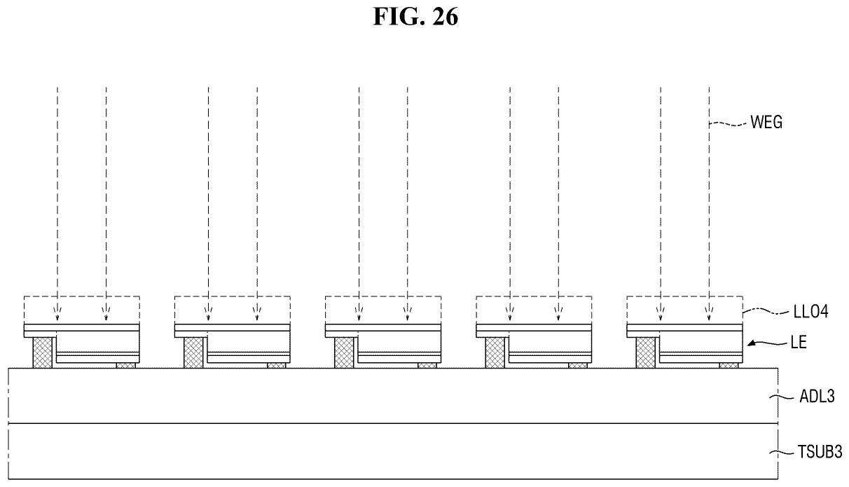

Fifth, as illustrated in FIGS. 25 and 26, the second laser separation layer LLO2 is irradiated with the laser to move the plurality of light emitting elements LE to a third adhesive layer ADL3 on a third transfer substrate TSUB3, and the second laser separation layer LLO2 is removed (step S115 in FIG. 20).

The third transfer substrate TSUB3 may be made of a transparent material to allow light to pass therethrough. For example, the third transfer substrate TSUB3 may include a transparent polymer such as polyimide, polyester, polyacrylic, polyepoxy, polyethylene, polystyrene, polyethylene terephthalate, and/or the like. The third adhesive layer ADL3 disposed on one surface of the third transfer substrate TSUB3 may include an adhesive material for adhering the plurality of light emitting elements LE. For example, the adhesive material may include urethane acrylates, epoxy acrylates, polyester acrylates, and/or the like.

When the second laser separation layer LLO2 is irradiated with the laser in a state in which the first electrode E1 and the second electrode E2 of each of the plurality of light emitting elements LE are in contact with the third adhesive layer ADL3 on the third transfer substrate TSUB3, the second laser separation layer LLO2 may be separated into a third laser separation layer LLO3 disposed on one surface of the second transfer substrate TSUB2 and a fourth laser separation layer LLO4 disposed on each of the plurality of light emitting elements LE.

Then, as illustrated in FIG. 26, the fourth laser separation layer LLO4 remaining on each of the plurality of light emitting elements LE may be removed through a wet etching process. The fourth laser separation layer LLO4 is etched using an etching material WEG in which the plurality of light emitting elements LE are not etched and only the fourth laser separation layer LLO4 is etched.

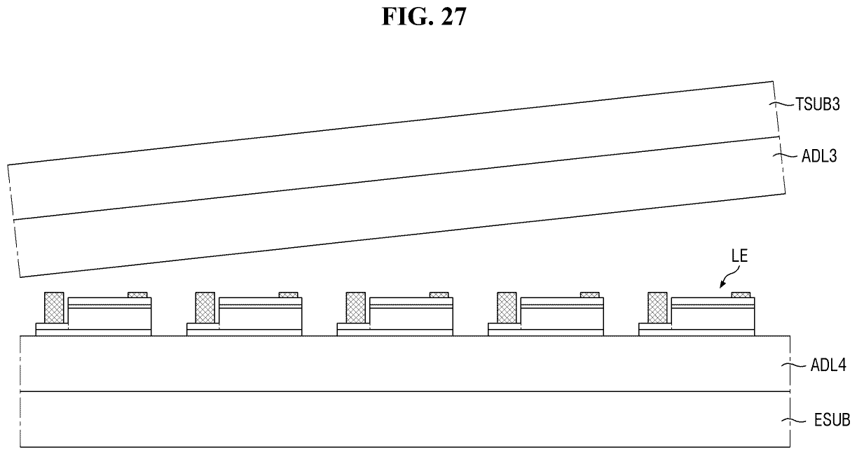

Sixth, as illustrated in FIG. 27, the plurality of light emitting elements LE on the third transfer substrate TSUB3 are moved to the fourth adhesive layer ADL4 on the light emitting element substrate ESUB (step S116 in FIG. 20).

Each of the plurality of light emitting elements LE is separated from the third adhesive layer ADL3 in a state in which one surface of each of the plurality of light emitting elements LE of the third transfer substrate TSUB3 is in contact with the fourth adhesive layer ADL4 on the light emitting element substrate ESUB. In this case, the tackiness of the fourth adhesive layer ADL4 may be greater than the tackiness of the third adhesive layer ADL3. One surface of each of the plurality of light emitting elements LE may be an opposite surface of the other surface on which the first electrode E1 and the second electrode E2 are disposed at each of the plurality of the light emitting elements LE.

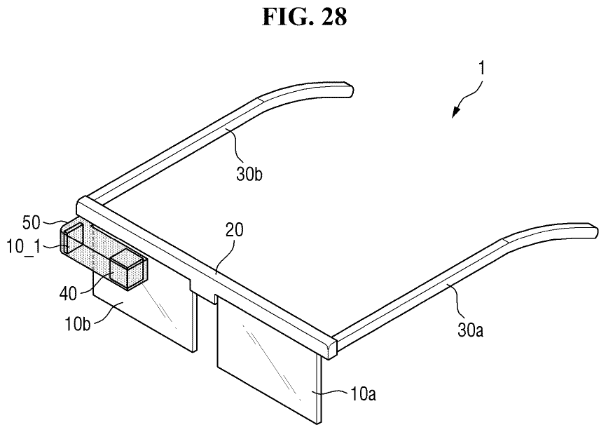

FIG. 28 is a diagram illustrating a virtual reality device including a display device according to one or more embodiments. FIG. 28 illustrates a virtual reality device 1 to which the display device 10_1 according to one or more embodiments is applied.

Referring to FIG. 28, the virtual reality device 1 according to one or more embodiments may be a glass-type device. The virtual reality device 1 according to one or more embodiments may include the display device 10_1, a left lens 10a, a right lens 10b, a support frame 20, temples 30a and 30b, a reflection member 40, and a display device storage 50.

Although FIG. 28 illustrates the virtual reality device 1 including the temples 30a and 30b, the virtual reality device 1 according to one or more embodiments may be applied to a head mounted display including a head mounted band that may be worn on a head, instead of the temples 30a and 30b. That is, the virtual reality device 1 according to one or more embodiments is not limited to that shown in FIG. 28, and may be applied in various forms to various electronic devices.

The display device storage 50 may include the display device 10_1 and the reflection member 40. The image displayed on the display device 10_1 may be reflected by the reflection member 40 and provided to a user's right eye through the right lens 10b. Accordingly, the user can view the virtual reality image displayed on the display device 10_1 through the right eye.

Although FIG. 28 illustrates that the display device storage 50 is disposed at the right end of the support frame 20, the present disclosure is not limited thereto. For example, the display device storage 50 may be disposed at the left end of the support frame 20, and in this case, the image displayed on the display device 10_1 may be reflected by the reflection member 40 and provided to a user's left eye through the left lens 10a. Accordingly, the user can view the virtual reality image displayed on the display device 10_1 through the left eye. Alternatively, the display device storage 50 may be disposed at both the left end and the right end of the support frame 20. In that case, the user can view the virtual reality image displayed on the display device 10_1 through both the left eye and the right eye.

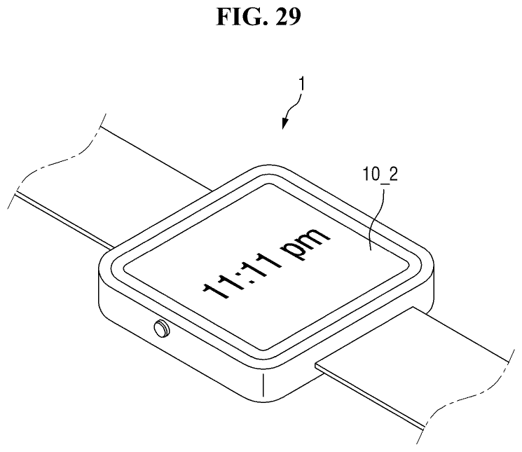

FIG. 29 is a diagram illustrating a smart watch including a display device according to one or more embodiments.

Referring to FIG. 29, the display device 10_2 according to one or more embodiments may be applied to a smart watch 2 that is one of the smart devices.

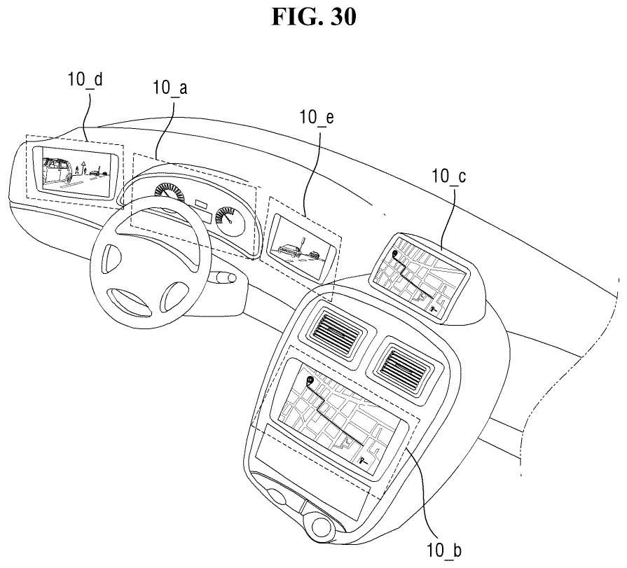

FIG. 30 is a diagram illustrating a dashboard of an automobile and a center fascia including display devices according to one or more embodiments. FIG. 30 shows an automobile to which the display device 10 according to one or more embodiments is applied.

Referring to FIG. 30, the display devices 10_a, 10_b, and 10_c according to one or more embodiments may be applied to the dashboard of the automobile, the center fascia of the automobile, or the center information display (CID) of the dashboard of the automobile. Further, the display devices 10_d, and 10_e according to one or more embodiments may be applied to a room mirror display instead of side mirrors of the automobile.

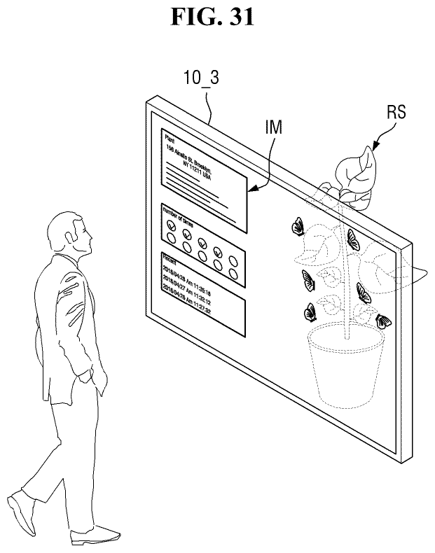

FIG. 31 is a diagram illustrating a transparent display device including a display device according to one or more embodiments.

Referring to FIG. 31, the display device 10_3 according to one or more embodiments may be applied to the transparent display device. The transparent display device may display an image IM, and also may transmit light. Thus, a user located on the front side of the transparent display device can view an object RS or a background on the rear side of the transparent display device as well as the image IM displayed on the display device 10_3. When the display device 10_3 is applied to the transparent display device, the substrate SUB of the display device 10_3 may include a light transmitting portion capable of transmitting light or may be made of a material capable of transmitting light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a bank on the substrate and comprising an opening;
a pixel electrode and a common electrode spaced from each other on the substrate in the opening;
an organic layer on the pixel electrode and the common electrode in the opening;
a light emitting element on the organic layer, and comprising a first electrode and a second electrode on a top surface thereof;
a first connection electrode connected to the pixel electrode and the first electrode of the light emitting element; and
a second connection electrode connected to the common electrode and the second electrode of the light emitting element,
wherein the organic layer is on a bottom surface and at least a portion of one side surface of the light emitting element.

2. The display device of claim 1, wherein the first connection electrode is on the organic layer between the bank and the one side surface of the light emitting element,
the second connection electrode is on the organic layer between the bank and an other side surface of the light emitting element, and
the other side surface of the light emitting element is a side surface opposite to the one side surface of the light emitting element.

3. The display device of claim 1, wherein a thickness of the organic layer is less than a thickness of the bank.

4. The display device of claim 1, wherein the light emitting element comprises:
a first semiconductor layer connected to the first electrode;
an active layer connected to the first semiconductor layer;
a second semiconductor layer comprising a first portion connected to the active layer and a second portion connected to the second electrode; and
an undoped semiconductor layer connected to the second semiconductor layer.

5. The display device of claim 4, wherein a thickness of the first portion of the second semiconductor layer is greater than a thickness of the second portion of the second semiconductor layer.

6. The display device of claim 4, wherein the undoped semiconductor layer is on the organic layer,
the second semiconductor layer is on the undoped semiconductor layer,
the active layer is on the first portion of the second semiconductor layer,
the first semiconductor layer is on the active layer,
the first electrode is on the first semiconductor layer, and
the second electrode is on the second portion of the second semiconductor layer.

7. The display device of claim 6, wherein a thickness of the second electrode is greater than a thickness of the first electrode.

8. The display device of claim 4, wherein the organic layer is on side and bottom surfaces of the undoped semiconductor layer and at least a portion of one side surface of the second semiconductor layer.

9. The display device of claim 4, wherein the first connection electrode is on one side surface of the first semiconductor layer, one side surface of the active layer, and at least a portion of one side surface of the second semiconductor layer.

10. The display device of claim 6, wherein the second connection electrode is on at least a portion of one side surface of the second electrode.

11. The display device of claim 10, wherein the second connection electrode is on at least a portion of a top surface and the entire one side surface of the second electrode.

12. The display device of claim 6, wherein the organic layer is on at least a portion of a top surface of the second portion of the second semiconductor layer.

13. The display device of claim 1, wherein an area of the organic layer is larger than an area of the first connection electrode and an area of the second connection electrode.

14. The display device of claim 1, wherein an area of the pixel electrode is larger than an area of the first connection electrode, and
an area of the common electrode is larger than an area of the second connection electrode.

15. The display device of claim 1, wherein the pixel electrode and the common electrode comprise an opaque metal material, and
the first connection electrode and the second connection electrode comprise a transparent conductive oxide.

16. The display device of claim 1, wherein a thickness of the bank is about 0.5 μm or more.

17. A method for manufacturing a display device, comprising:
preparing a plurality of light emitting elements on a light emitting element substrate;
forming a bank having a plurality of openings on a substrate, and forming a pixel electrode and a common electrode in each of the plurality of openings;
forming an organic layer on the pixel electrode and the common electrode in each of the plurality of openings;
adhering each of the plurality of light emitting elements of the light emitting element substrate to the organic layer in each of the plurality of openings; and
forming a first connection electrode connecting the pixel electrode to a first electrode of the light emitting element on the organic layer, and a second connection electrode connecting the common electrode to a second electrode of the light emitting element.

18. The method of claim 17, further comprising:
forming a light blocking layer on the bank;
forming a first light conversion layer in a region corresponding to a first sub-pixel, forming a second light conversion layer in a region corresponding to a second sub-pixel, and forming a light transmitting layer in a region corresponding to a third sub-pixel, from among regions partitioned by the light blocking layer; and
forming a first color filter on the first light conversion layer, forming a second color filter on the second light conversion layer, and forming a third color filter on the light transmitting layer.

19. The method of claim 17, wherein the adhering of each of the plurality of light emitting elements of the light emitting element substrate to the organic layer in each of the plurality of openings comprises:
curing the organic layer in each of the plurality of openings at a first temperature;
inserting a portion of each of the plurality of light emitting elements into the organic layer in each of the plurality of openings; and
curing the organic layer at a second temperature higher than the first temperature.

20. The method of claim 17, wherein the adhering of each of the plurality of light emitting elements of the light emitting element substrate to the organic layer in each of the plurality of openings comprises:
detaching each of the plurality of light emitting elements from the light emitting element substrate by using a stamp having an adhesive layer;
inserting a portion of each of the plurality of light emitting elements into the organic layer in each of the plurality of openings; and
detaching each of the plurality of light emitting elements from the stamp by applying heat to the adhesive layer of the stamp.

21. A display device comprising:
a substrate;
a pixel electrode and a common electrode spaced from each other on the substrate;
an insulating layer on the substrate, and at least partially overlapping the pixel electrode and the common electrode;
a light emitting element on the insulating layer, and comprising a first electrode and a second electrode;
a first connection electrode electrically connected to the pixel electrode and the first electrode of the light emitting element; and
a second connection electrode electrically connected to the common electrode and the second electrode of the light emitting element,
wherein at least one of the first electrode or the second electrode of the light emitting element comprises an area exposed by the insulating layer.
